(19) United States
(12) Patent Application Publication
(10) Pub. No.: US 2024/0349521 A1
(43) Pub. Date: Oct. 17, 2024

(54) DEVICES AND METHODS INVOLVING DIELECTRIC-BASED MATERIAL INTEGRATED WITH SENSORY-BASED FEEDBACK AND/OR TRANSISTOR(S)

(71) Applicant: The Board of Trustees of the Leland Stanford Junior University, Stanford, CA (US)

(72) Inventors: Weichen Wang, Stanford, CA (US); Zhenan Bao, Stanford, CA (US)

(21) Appl. No.: 18/627,006

(22) Filed: Apr. 4, 2024

Related U.S. Application Data
(60) Provisional application No. 63/457,550, filed on Apr. 6, 2023.

(51) Int. Cl. H10K 10/46; G06N 3/065; H10K 19/00

(52) U.S. Cl. CPC H10K 10/474; G06N 3/065; H10K 10/471; H10K 19/901

(57) ABSTRACT

Certain examples include an elastic transistor having multiple layers, as a monolithic IC, to provide a stretchable high-k multi-layer dielectric that in response to a low-drive voltage, operates to provide (stable or steady-state) operation. The stretchable layers include: a high-k dielectric layer, and another dielectric layer, with the high-k dielectric layer being between the gate of the elastic transistor and the other dielectric layer. More-specific examples, useful in combination, have two types of the above-characterized elastic transistors cooperatively arranged and respectively implemented as a semiconductor with multiple different dielectric materials and as a synaptic transistor with the high-k dielectric layer including a border interface region characterized as one of a polycation interface and a polyanion interface and with the other dielectric layer corresponding to an interfacial portion along an outer border of the high-k dielectric layer.

### BACKGROUND

Aspects of the present disclosure are related generally to the field of thin artificial sensors, as may be exemplified by uses in applications such as (but not limited to) low-voltage driven soft electronics for wearable devices, bio-interface and neuromorphic devices, and to a wide range of semiconductor applications which would benefit from or use stretchable transistors having polymeric-based dielectrics.

Referring to one such technology type, electronic skin (aka artificial skin or “e-skin”) for case of discussion, it has been appreciated that skin enables one's interactions with the physical world. E-skin can play a relatively important role as the primary interface and protection between human body and the surrounding world. The combination of sensory capabilities and mechanical softness of skin can enable effortless perceptions and responses to various external stimuli, and also allow beings to perform complex tasks in both dynamic and unstructured environments. Unfortunately, patients suffering from skin damage or amputation may have severely perturbed perception-action loops, causing them to struggle even in simple tasks like object grasping. Although prosthetic limbs can partially restore motor functions, limitations of known prosthetic limb designs are associated with phantom limb pain, uncontrolled movements, and poor dexterity. Efforts directed to enabling a natural human-machine interface and conferring the electronic systems to mimic different biological attributes (e.g., by using skin-like properties) attempt to embody skin-like perceptual capability in prosthetics and robotics. Despite advancements in such flexible electronics and circuit fabrication, their practical (e-skin) applications have been limited by requirements of relatively-rigid circuit-related technologies and/or an inability to adequately integrate such technologies for mimicking the biological attributes as needed for providing the advantages of safety and good tissue conformability, with minimal invasiveness, imperceptibility, low-power operation and/or stability in physiological environments. For example, certain previous, stretchable organic electronics require a high operation voltage (e.g., 30-100 V), which generates safety and power consumption concerns.

Artificial skin that simultaneously mimics the sensory feedback and mechanical properties of natural skin holds significant promise for next-generation robotic and medical devices. However, achieving such a biomimetic system with such adequate biological attributes and with seamless integration for the human body remains a great significant challenge.

These and other matters have presented challenges to efficiencies of soft and/or stretchable electronic-based material implementations, for a variety of applications.

### SUMMARY OF VARIOUS ASPECTS AND EXAMPLES

Various examples/embodiments presented by the present disclosure are directed to issues such as those addressed above and/or others which may become apparent from the following disclosure. In specific contexts, certain examples and exemplary aspects of the present disclosure are directed to mitigating and/or solving one or more problems encountered by previously-reported devices. One such problem concerns currently-available intrinsically stretchable organic electronics which require a high operation voltage (e.g., 30-100 V) and which may result in safety and power consumption concerns. Also addressed by exemplary aspects of the present disclosure, such problems may concern one or more of: an undesirable trade-off between high capacitance and high transistor performance for previously-developed stretchable transistors; and polymeric-based dielectrics used in such devices becoming unstable when submerged (e.g., in aqueous solutions); instability more generally for such devices having small material-based parameters (low levels of thickness of less than about 500 nm) and inclusion of liquid and/or gel components which manifest poor environmental stabilities or rigid materials with limited tissue conformability. More specifically, one example type of transistor or dielectric is characterized as being all solid-state because such specific transistors and dielectric materials of the present disclosure provide or maintain the stretchability attributes of the transistor or dielectric (e.g., with stable operation during submersion attributable being non-soluble in an aqueous solution). In certain examples, the dielectric materials have no soluble parts in aqueous solution which may be important in some applications because, by including an ionic liquid or a small molecule salt as such, the compound will dissolve and become unstable when exposed to water (e.g., when submerged). This specific example is in contrast to certain previously-reported structures which are not stable as such, because they rely on liquid or gel as part of the stretchable dielectric.

In certain examples, methods and semiconductor structures involve an elastic transistor having multiple layers integrated with the transistor into a single constitution to provide a stretchable high-k multi-layer dielectric that in response to a low-drive voltage, operates to provide steady-state operation (e.g., with electrons and/or holes flowing through the multiple layers between the transistor's source and the drain). The multiple layers include: a stretchable high-k dielectric layer, and at least one other stretchable dielectric layer, with the stretchable high-k dielectric layer being between the gate of the elastic transistor and the at least one other stretchable dielectric layer. In each instance, individually and/or collectively, the high-k value is not less than four.

In certain examples, methods and semiconductor structures involve an elastic transistor having multiple layers integrated with the transistor into a single constitution to provide a stretchable high-k multi-layer dielectric that in response to a low-drive voltage, operates to provide operation (e.g., with electrons and/or holes flowing through the multiple layers between the transistor's source and the drain). The multiple layers include: a stretchable high-k dielectric layer, and at least one other stretchable dielectric layer, with the stretchable high-k dielectric layer being between the gate of the elastic transistor and the at least one other stretchable dielectric layer. The high-k value of the stretchable high-k multi-layer dielectric and/or the stretchable high-k dielectric layer (i.e., collectively or individually) is not less than four, and in some examples much higher such as at about or above 10 and 50.

In certain other examples, the present disclosure is directed to methods involving use or manufacture of such an elastic transistor. One such example method includes: operating an elastic transistor, in response to a driving voltage while the elastic transistor is being stretched under a strain of at least 25% and causing, while the elastic transistor is being operated in response to the driving voltage, electrons and/or holes to flow via a stretchable high-k multi-layer dielectric that is electrically arranged between the source and the drain. In this example method, the stretchable high-k multi-layer dielectric has integrated layers including a stretchable high-k multi-layer dielectric and at least one other stretchable dielectric layer, with the stretchable high-k dielectric layer being closer to the gate of the elastic transistor than the other dielectric layer (dielectric constant, k, in each occurrence is not less than four and in more specific examples not less than three).

Certain more-specific examples include a second elastic transistor, also as characterized above, and these transistors are used in combination, for example, with one as a synaptic transistor and another as a semiconductor transistor (e.g., located in proximity to, connected via cables or wirelessly, and/or fixedly secured to an e-skin constitution having the synaptic transistor), the latter being part of a logic circuit to process (e.g., amplify) signals driving, or in response to, signals from the sensor circuitry which includes the synaptic transistor. In the synaptic transistor, the other stretchable dielectric layer corresponds to an interfacial portion along an outer border or boundary of the high-k dielectric layer as a blend of the high-k dielectric layer and the immediately-adjacent substrate material at which cations or anions are fixed to a polymer substrate (e.g., the blend characterized as one of a polycation interface and a polyanion interface having thickness in a range of one to several atomic layers or sufficient to embrace the portion thereof having the fixed polycations or polyanions. For the semiconductor transistor, its stretchable high-k multi-layer dielectric may use a nitrile-based synthetic in the stretchable high-k dielectric layer and an ultra-thin a low-k dielectric for its other stretchable dielectric layer.

In some specific example aspects, methods and devices use, or leverage from, an integrated (e.g., e-skin like) constitution including a sensor (e.g., pressure and/or temperature) that is structurally integrated with at least one dielectric material. The sensor includes active circuitry to detect, via signal conditioning and closed-loop actuation, stimuli generated concurrently in multiple modalities. The dielectric material is structurally integrated with the sensor to enable flexibility under significant levels of elastic strain (e.g., 25%, 50% and/or 100%) without breaking. For instance, as used on a human figure, the high-k dielectric material is structurally integrated with the sensor to be both flexible and reversibly stretchable.

In one specific embodiment according to the present disclosure, an apparatus includes: a sensor with active circuitry including multiple pressure sensors and multiple temperature sensors (e.g., from a few to several pressure and temperature sensors) to detect, via signal conditioning and closed-loop actuation, stimuli generated concurrently in multiple modalities from a living biological structure; and at least one dielectric layer. The at least one dielectric layer is structurally integrated with the sensor into an integrated constitution that enables the integrated constitution to conform to the living biological structure by being flexible under clastic strain without breaking and/or reversibly stretchable.

In another specific embodiment according to the present disclosure, a method includes sensing stimuli generated concurrently in multiple modalities. The sensing is performed by way of signal conditioning circuitry, closed-loop actuation circuitry and at least one layer including a dielectric. The circuitries and the at least one layer are integrated into a single constitution that is flexible and/or reversibly-stretchable.

In further specific example embodiments, aspects of the present disclosure involve and/or are directed to examples and/or aspects that involve one or more (in any of various combinations) of the following: a stretchable dielectric in sensor-based and/or circuit-based coverings; a stretchable dielectric designed for use with or in a low-voltage driven transistor; a solid-state stretchable synaptic transistor; a stretchable high-κ tri-layer dielectric design for low-voltage driven transistor; and a stretchable ionic dielectric design for circuitry having a (e.g., all-solid-state and/or intrinsically stretchable) synaptic transistor.

In non-limiting exemplary contexts, aspects and examples of the present disclosure are directed to improvements in connection with dielectric-based materials useful for stretchable and/or electronic coverings and these may include e-skin and other types of sensors. As more specific examples, such coverings may be implemented as partial patches such as may be used on or within a living entity (e.g., on a structure within or attached to a live entity for monitoring a medical condition or reaction).

In other example aspects, the present disclosure is directed to designs involving improved stretchable dielectric materials as may be used in connection with e-skin for neuroprosthetics, other material-based sensors which are to mimic biological sensory receptors (e.g., in bio-interface devices and materials, neuromorphic devices, and other robotic and/or medical devices), and soft and/or stretchable electronics benefiting from multi-layer low-voltage-driven (e.g., wearable) devices.

The above discussion is not intended to describe each aspect, embodiment or every implementation of the present disclosure. The figures and detailed description that follow also exemplify various embodiments.

### BRIEF DESCRIPTION OF FIGURES

Various example embodiments, including experimental examples, may be more completely understood in consideration of the following detailed description and in connection with the accompanying drawings, each in accordance with the present disclosure, in which:

FIG. 1A is a diagram showing attributes and implementation aspects of an e-skin design including a synaptic transistor, according to certain exemplary embodiments of the present disclosure;

FIG. 1B is a schematic showing overall flow and exemplary embodiment (e.g., with previously-separated ring-oscillator and edge-detector circuits) integrated as part of an overall e-skin-sensorized-neuromorphic system implemented in a manner consistent with certain examples of the present disclosure;

FIG. 2A is a set of related diagrams, including a schematic and corresponding graphs, showing exemplary device structures and operation for a certain example implementation consistent with the present disclosure;

FIG. 2B is a related graph depicting dielectric constant versus frequency, according to certain exemplary aspects of the present disclosure;

FIG. 2C is a graph-type diagram showing mobility and water contact angle parameters, according to certain exemplary aspects of the present disclosure;

FIG. 2D is a bar graph showing comparison of activation energy and for different dielectrics, according to certain exemplary aspects of the present disclosure;

FIG. 2E is a graph showing comparisons involving different dielectric parameters, according to certain exemplary aspects of the present disclosure;

FIG. 2F is a graph showing comparisons involving previously-reported transistors relative to example embodiments according to the present disclosure;

FIG. 2G is another graph showing comparisons involving previously-reported transistors relative to example embodiments according to the present disclosure;

FIG. 2H is yet another graph showing comparisons involving previously-reported transistors relative to example embodiments according to the present disclosure;

FIG. 3A is a schematic diagram showing a natural perception process consistent with certain exemplary aspects of the present disclosure;

FIG. 3B is a depiction of a soft e-skin patch or cover material on a finger or digit as a specific example implementation of a biomimetic stretchable circuit, according to the present disclosure;

FIG. 3C is a depiction of a reversibly stretchable and flexible transistor, according to certain exemplary aspects of the present disclosure, with sensory information encoding, a ring oscillator and an edge detector;

FIG. 3D is an image a e-skin on a finger, consistent with certain exemplary aspects of the present disclosure;

FIG. 3E is a schematic diagram showing an example design of a sensing inverter, according to certain exemplary aspects of the present disclosure;

FIG. 3F, including subparts (i) and (ii), depicts a pair of related graphs showing parameters of a ring oscillator for digitization, according to certain exemplary aspects of the present disclosure;

FIG. 3G, including subparts (i) and (ii), is a pair of graphs respectively reflecting parameters associated with a pulse-generating edge detector, according to certain exemplary aspects of the present disclosure;

FIG. 3H including subparts (i), (ii) and (iii) are respectively a depiction of a pressure sensor with pyramidal structures and a pair of related graphs showing responsiveness to pressure and temperature, according to certain exemplary aspects of the present disclosure;

FIG. 3I is a related graph showing different pulse train frequencies from a pressure sensor system, according to certain exemplary aspects of the present disclosure;

FIG. 3J is a related example bar graph showing a pulse train frequency relative to pressure on a sensor, according to certain exemplary aspects of the present disclosure;

FIG. 3K is a graph showing comparisons involving previously reported circuits relative to example embodiments, according to certain exemplary aspects of the present disclosure;

FIG. 4A is a diagram showing implementation of an artificial synaptic transistor, according to certain exemplary aspects of the present disclosure;

FIG. 4B is a type of example embodiment, according to certain exemplary aspects of the present disclosure, with a synaptic transistor and ionic conductive elastomer;

FIG. 4C is a diagram showing implementation of a related biological synapse consistent with exemplary aspects of the present disclosure;

FIG. 4D is a pair of related diagrams showing correlation between pre-synaptic pulse train frequency and post-synaptic current amplitude, according to certain exemplary aspects of the present disclosure;

FIG. 4E is a graph depicting a related set of transfer curves relative to post-synaptic current distribution, according to certain exemplary aspects of the present disclosure;

FIG. 4F is a diagram showing comparisons of stability attributes for different dielectric composites, according to certain exemplary aspects of the present disclosure;

FIG. 4G is a diagram showing results of stability tests for ten synaptic transistors, according to certain exemplary aspects of the present disclosure;

FIG. 5A is an example schematic diagram disclosing certain exemplary aspects in an experimental implementation of the present disclosure;

FIG. 5B is a related example graph showing a pulse train frequency relative to pressure on a sensor, according to certain exemplary aspects of the present disclosure;

FIG. 5C is an example bar graph showing responsiveness under different signal gating frequencies also for the experimental implementation of FIG. 5A, according to certain exemplary aspects of the present disclosure;

FIGS. 5D and 5E are example plots also for the experimental implementation of FIG. 5A, respectively showing stimulation responses and evoked signal responses, according to certain exemplary aspects of the present disclosure;

FIG. 5F is an example bar graph showing correlation of leg twitching angle and applied pressure also for the experimental implementation of FIG. 5A and according to certain exemplary aspects of the present disclosure;

FIGS. 6A-6F are examples of known high-k dielectrics, exemplifying certain exemplary aspects for examples of the present disclosure, with each of FIGS. 6A, 6B and 6C respectively characterizing such dielectrics as elastomer-type materials, and each of FIGS. 6D, 6E and 6F respectively characterizing such dielectrics as polymer-type materials; and

FIGS. 7A-7D are examples of known solid-state (single-ion-type) conductors, exemplifying certain exemplary aspects for examples of the present disclosure, with FIG. 7A characterizing a conductor with tunable anionic mobile ions in, FIG. 7B characterizing a conductor with tunable cationic mobile ions conductor, FIG. 7C characterizing a conductor with tunable cationic fixed backbone ions, and FIG. 7D characterizing a tunable anionic fixed backbone ions.

While various embodiments discussed herein are amenable to modifications and alternative forms, certain aspects thereof are disclosed by examples in the drawings and the following description. It should be understood that such examples are representative and not necessarily limiting the scope of the disclosure. In addition, the term “example” as used throughout this application is only by way of illustration, and not limitation.

### DETAILED DESCRIPTION

Various aspects and examples according to the present disclosure (including the Appendices of the underlying U.S. provisional patent application) are directed to issues such as those addressed above and/or others which may become apparent from the following disclosure, and regarding apparatuses and methods involving transistors having high-k stretchable dielectric as may be useful, but not necessarily limited to, examples involving semiconductor transistors and/or synaptic transistors (e.g., as may be used in e-skin circuit-based systems). While the present disclosure is not necessarily limited to such aspects, an understanding of specific examples in the following description may be understood from discussion in such specific contexts.

Accordingly, in the following description various specific details are set forth to describe specific examples presented herein. It should be apparent to one skilled in the art, however, that one or more other examples and/or variations of these examples may be practiced without all the specific details given below. In other instances, well-known features have not been described in detail so as not to obscure the description of the examples herein. For case of illustration, the same reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

Certain examples of the present disclosure are directed to apparatuses and methods (of use and manufacture of such apparatuses), with such an apparatus including an elastic transistor having multiple layers integrated with the transistor into a single constitution to provide operation through a stretchable high-k multi-layer dielectric responds to a low-drive voltage. The multiple layers include: a stretchable high-k dielectric layer, and at least one other stretchable dielectric layer, with the stretchable high-k dielectric layer being between the gate of the elastic transistor and the at least one other stretchable dielectric layer. Each above occurrence of “high-k” refers to one or more values of a dielectric constant that, whether individually or collectively, is not less than four.

In certain examples, methods and semiconductor structures build on one or a combination of the above aspects, and are directed to, as examples: the elastic transistor being configured as a semiconductor transistor with the high-k layer including a synthetic rubber derived from different organic compounds, and the at least one other stretchable dielectric layer including a passivation material, wherein the high-k layer and said at least one other stretchable dielectric layer are cooperatively arranged to provide a dielectric-semiconductor interface that facilitates reduced or minimum trap density for efficacious charge transportation and small transistor hysteresis; and with at least one of the following: the stretchable high-k multi-layer dielectric having a dielectric constant of not less than 10 (in some examples, not less than 20), and the stable operation manifests a carrier mobility of greater than 0.1 cm²/V-per-sec; the stretchable high-k multi-layer dielectric providing stretchability attributes (e.g., stretchability under a strain of at least 25%, 50% or 100%), during normal operation.

In certain more specific examples applicable to ultra-thin coverings and/or e-skin systems, methods and semiconductor structures of the present disclosure are directed to a thin integrated constitution that includes a sensor structurally integrated with dielectric material (i.e., a material-based structure of one or more layers including a functionally-relevant amount of dielectric). The sensor includes active circuitry to detect, via signal conditioning and closed-loop actuation, stimuli generated concurrently in multiple modalities. The dielectric material is structurally integrated with the sensor to enable at least one of flexible under elastic strain without breaking, and reversibly stretchable. For instance, as used on a human figure, the dielectric material is structurally integrated with the sensor to be both flexible and reversibly stretchable. In more specific examples, the dielectric material is a high-κ multiple-layer dielectric including a layer with a synthetic rubber derived from different organic compounds, one of which is linked to nitrile (e.g., Acrylonitrile), wherein the active circuitry (circuits or circuitries, depending on terminology and/or implementation) and the dielectric are integrated into a single constitution that is flexible or reversibly-stretchable. In various examples, the integrated constitution may be implemented to include and/or used to form: a monolithic e-skin or e-covering system with a plurality of flexible electronic components and is to emulate sensory feedback functions of a sensorimotor loop in biological skin; a thin (e.g., e-skin) covering to provide sensory stimulation to the nervous system in a live being or to provide a neuromorphic system to emulate simultaneously closed-loop sensory encoding and mechanical softness of natural skin.

In one type of specific example according to the present disclosure, embodiments are directed to methods and/or semiconductor structures for forming an e-skin constitution including a sensor that is structurally integrated with a (e.g., high-κ) dielectric material. The sensor includes active circuitry (e.g., transistor circuitry) to detect, via signal conditioning and closed-loop actuation, stimuli generated concurrently in multiple modalities. The dielectric material is structurally integrated with the sensor to enable at least one of flexible under elastic strain without breaking, and reversibly stretchable.

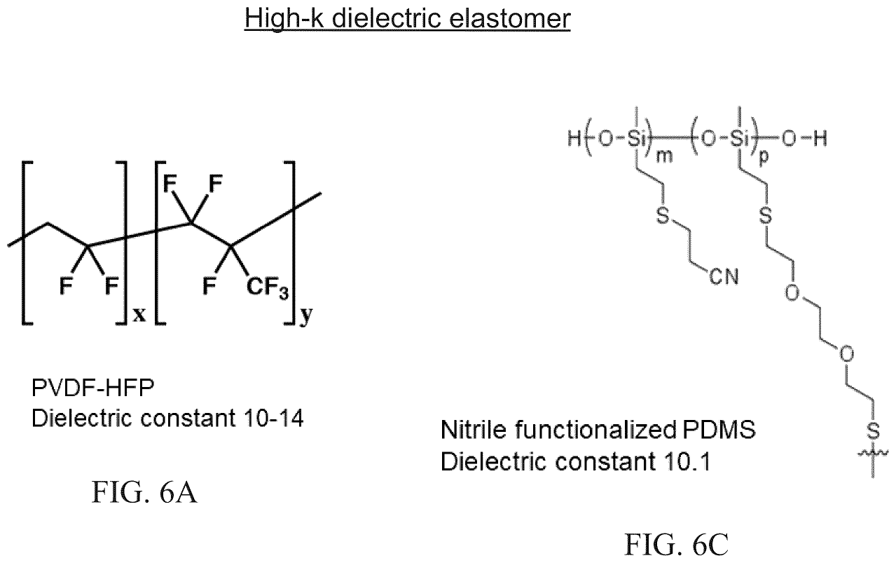

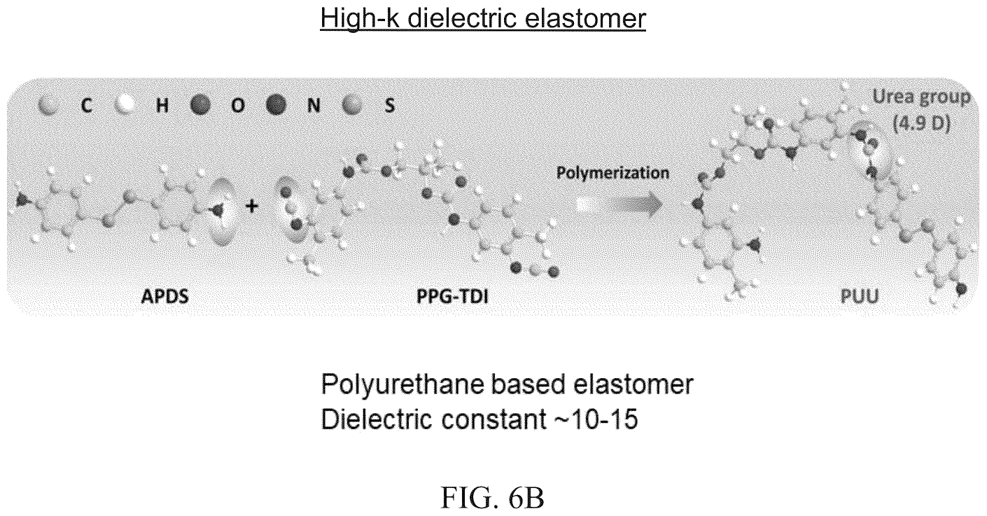

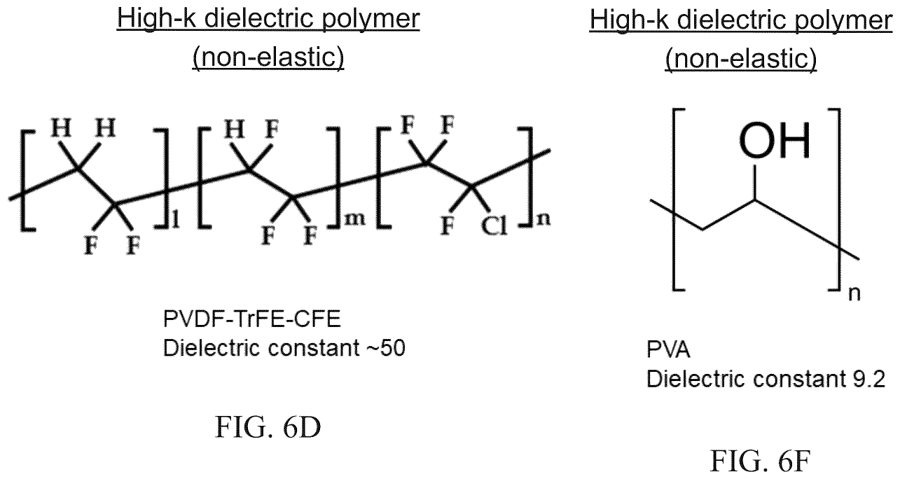

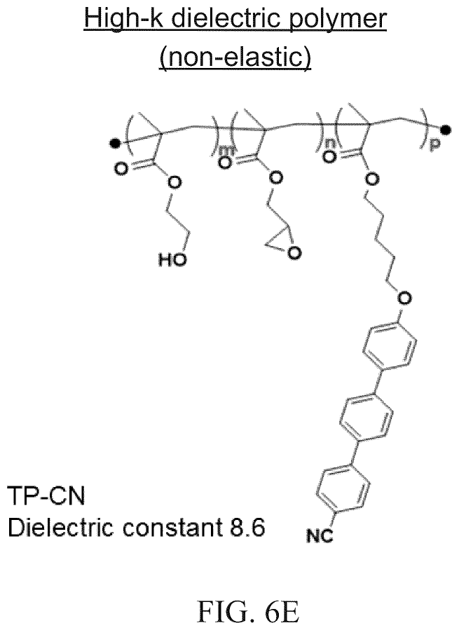

In more-specific example embodiments, the dielectric material is a high-κ multiple-layer dielectric stack including: a first layer with a synthetic rubber derived from one or more organic compounds (e.g., acrylonitrile and butadiene), such as to form nitrile butadiene rubber (NBR); a layer with a surface treated with OTS (octadecyltrimethoxysilane); and a type of passivation layer referred to as SEBS (styrene-ethylene-butylene-styrene). Also according to the present disclosure, chemistry-modified examples of the first layer in such a multi-layer high-k dielectric material, one (or possibly a combination) of the chemical structures shown in FIGS. 6A-6F may be used in place of (or possibly to complement) the first (e.g., NBR) layer.

Further, such examples may further include or involve the active circuitry including the synaptic transistor circuitry and implemented to include functionally-specific circuitry such as soft-ring oscillators, edge-detection circuitry and/or amplitude-decoupled frequency modulation, with such circuitry configured for processing signals derived from the stimuli and/or for sensing the stimuli (e.g., all while the stimuli is generated from a live being). In these and/or other specific examples,

In certain related examples, the active circuitry (e.g., transistors) is capable of being driven by a low voltage, corresponding to a voltage from 30 V to 0.5 V (or in some example, the low driving voltage is in a range of 10 V to 0.5 V, or 3 V to 0.5 V), and/or with mobility optimized for sensing the stimuli while the stimuli is generated from a live being, sub-threshold swing (SS) down to 85 mV per decade, and minimized power dissipation for a given application. In certain more-specific/experimental examples, the active circuitry (e.g., via one or more transistor arrays) exhibits an average mobility on the order of 2.01 cm²V⁻¹ s⁻¹, and minimized power dissipation on the order of 1.7 pJ.

In related more-specific examples, the active circuitry is configured with at least some of the transistors arranged in transistor arrays to exhibit a combination of at: stretchability (e.g., characterized as being in a range from 25% strain up to 100% strain). In one such specific array-based example, solid-state synaptic transistors are configured as pressure sensors and/or temperature sensors. Further, whether or not implementing such circuitry via arrays as such, the active circuitry may be implemented as at least part of one or more soft-ring oscillators, one or more edge-detectors, and/or for amplitude-decoupled frequency modulation in an application-specific tunable range (e.g., with the range being for biomimetic perception of the generated stimuli).

Exemplary aspects of the present disclosure are related to certain experimental efforts and example embodiments, in which the designs and engineering of material properties, device structures, and system architectures, are realized via a monolithic soft prosthetic e-skin without using (and/or necessarily needing) rigid electronic components. Such example designs are capable of multimodal sensing, neuromorphic pulse train signal generation, and closed-loop actuation.

In certain examples which involve use of a multi- or tri-layer high-κ elastomeric dielectric in designs according to the present disclosure, at least one or a combination of the following is realized: the driven-voltage of stretchable transistors can be reduced from 30-100V to 3-5V, which is significantly beneficial in terms of the safety and power consumption concerns; the design allows for low operation voltage and high carrier mobility simultaneously; provision of a dielectric-semiconductor interface (e.g., optimized for a specific e-covering application) to help achieve a record-low subthreshold swing for stretchable transistor; and improvements in terms of dielectric capacitance and strength (e.g., 10-fold, 20-fold and in some instances 30-fold capacitance increasing compared to previously-reported SEBS single layer dielectric). It is appreciated that a high-k value for such a dielectric depends on the chemistry of the dielectric (e.g., a value of about 3.9 or 4.0 is considered high-κ).

For certain multi- or tri-layer high-κ elastomeric dielectrics according to the present disclosure, a low sub-threshold swing is achieved (e.g., up to 85 mV per decade) which is comparable to poly-Si transistors, low operation voltage (±0.75 V), low static power consumption 10 (e.g., 0.25 pW), and medium-scale circuit integration complexity for stretchable organic devices. Finally, such e-skin (a.k.a. e-covering) has been realized according to the present disclosure as being useful in successfully sensorizing (e.g., mimicking) a live animal's nervous system, and also useful in mimicking the biological sensorimotor loop where a solid-state synaptic transistor has been shown to elicit stronger muscle actuation under the application of increased pressure stimuli.

Consistent with the above aspects, such a manufactured device or method of such manufacture may involve aspects presented and claimed in U.S. Provisional Application Ser. No. 63/457,550 filed on Apr. 6, 2023 (STFD.454P1 S22-405) with Appendices A-B, to which priority is claimed. To the extent permitted, such subject matter is incorporated by reference in its entirety generally and to the extent that further aspects and examples (such as experimental and/or more-detailed embodiments) may be useful to supplement and/or clarify.

In certain more-detailed or experimental examples, a multi- or tri-layer dielectric stack is developed for a low voltage transistor that is operable with a significantly-reduced driving voltage of intrinsically stretchable transistor from previously reported 30-100V to 3-5V, without sacrificing the transistor's on-current and on/off ratio. In certain specific contexts according to examples of the present disclosure, such low voltages are in a voltage range from 30 V to 0.5 V. In certain detailed examples (e.g., experimental proof of concept), such a multi-layer dielectric stack may consist of two or three or several layers, wherein each layer may be characterized by its chemical composition (e.g., chemical compound(s) such as may be patterned by lithography or coated, etc.) and/or characterized at the atomic level such by an interfacial surface portion.

One such dielectric stack, consistent with the multi-layer dielectric stack discussed above, is a tri-layer stack for a stretchable semiconductor-type transistor. The tri-layer stack includes a high-k NBR, with an ultra-thin non-polar poly SEBS elastomer coating (˜15 nm) as another (middle) layer, followed by a hydrophobic OTS molecular modification as another (outer) layer. The SEBS passivation layer and OTS modification layer (e.g., when the latter is used in combination for certain limited examples) provide an ideal dielectric-semiconductor interface with minimum trap density for efficacious charge transportation and small transistor hysteresis. Compared to previously-used SEBS dielectric, certain examples with such a tri-layer dielectric boost the capacitance value for 30-fold and highly improves dielectric strength. Leveraging or benefiting from the surface modification, in such experimentation a record-low subthreshold swing (SS, 85 mV per decade) is achieved for stretchable transistors, which is comparable to rigid polycrystalline Si (poly-Si) transistors.

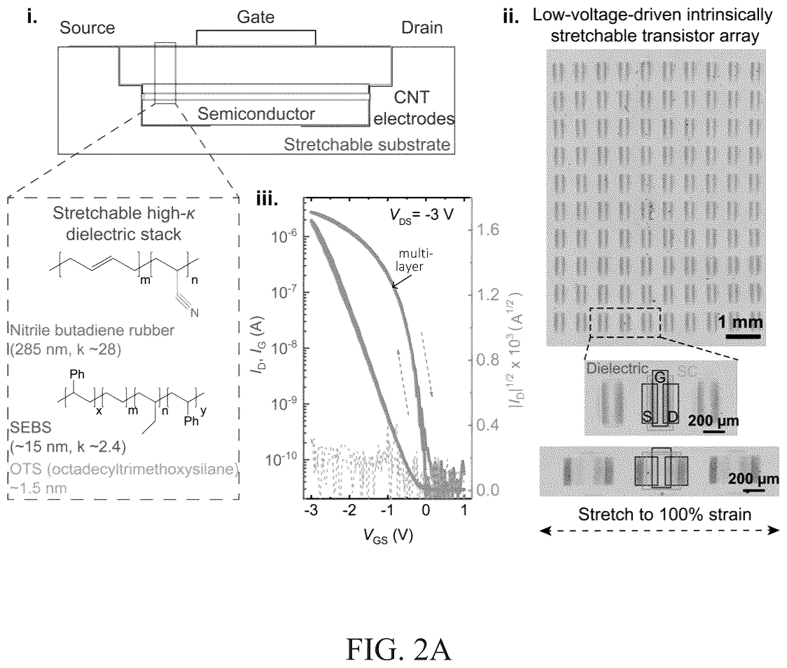

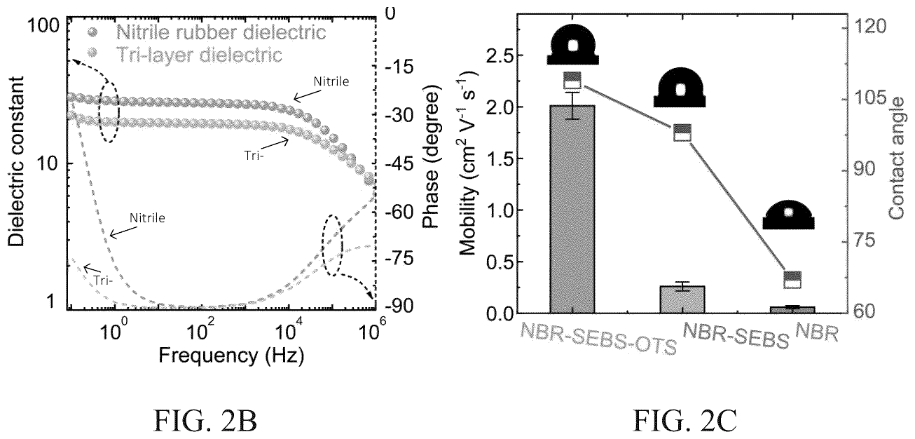

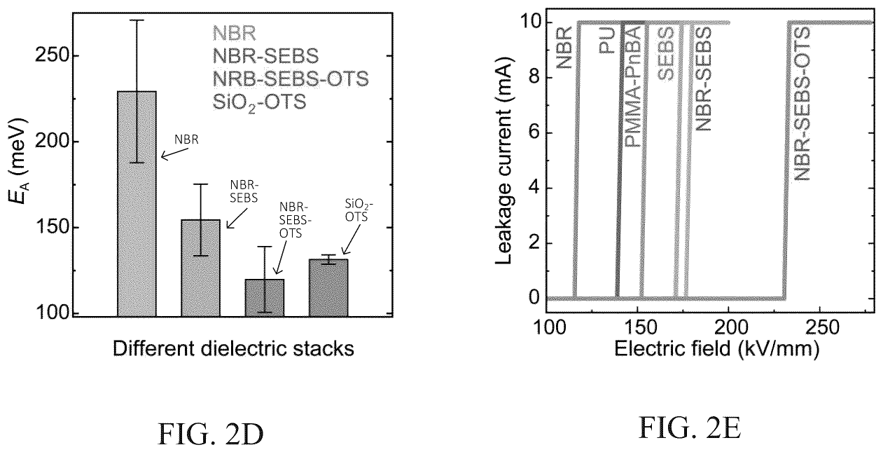

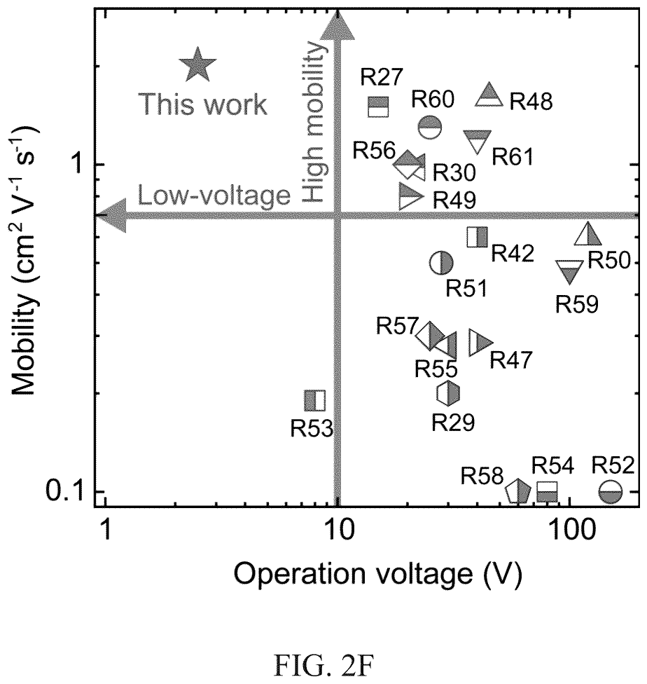

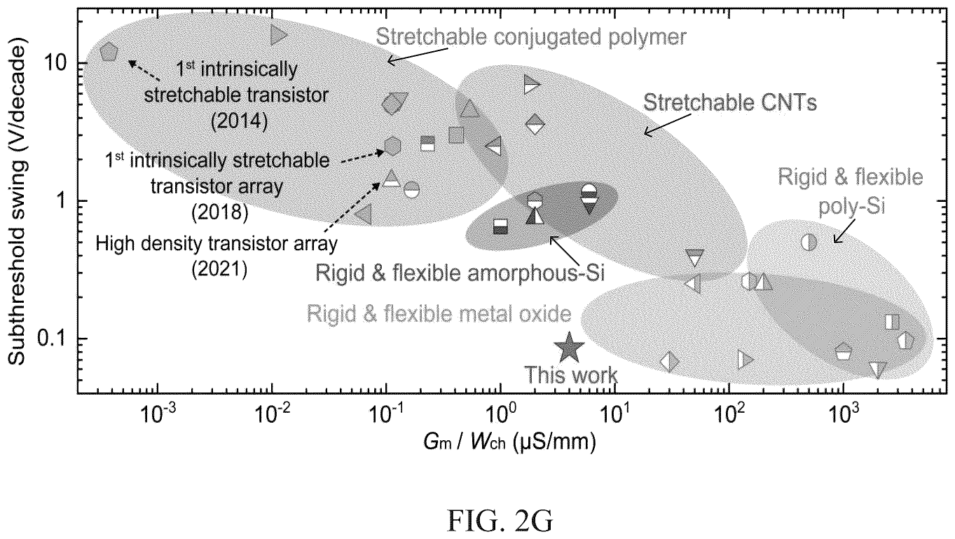

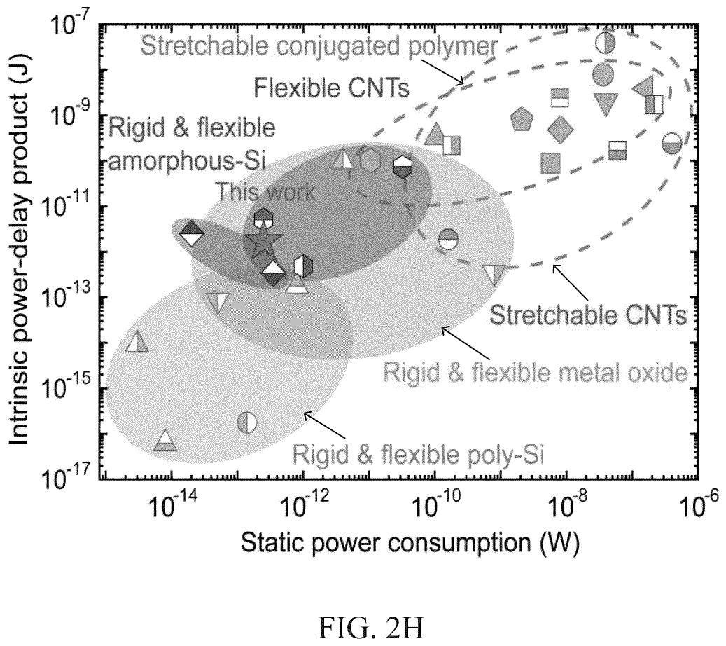

In certain more-specific examples, aspects of the present disclosure are directed to soft and/or flexible dielectric-based devices being implemented with a high-κ multi-layer (e.g., tri-layer) dielectric and/or a synaptic switch (e.g., transistor). Such a high-κ multi-layer may have one or more of the following attributes: reduced driven-voltage of stretchable transistors (e.g., from 30-100V by a magnitude of order such as to under 15V or to 3-5V) which is beneficial in terms of the safety, reduced power consumption and longer operation without requiring servicing (recharging/replacement); low-operation voltage and high carrier mobility of at least 0.1 cm²V⁻¹s⁻¹ (e.g., as in the graphs of FIG. 2C/FIG. 2D with >0.4 cm²V⁻¹s⁻¹ via NBR-SEBS, and with >1.0 cm²V⁻¹s⁻¹ via NBR-SEBS) at the same time; a dielectric-semiconductor interface which is configured to achieve a minimized or optimized low subthreshold swing for stretchable transistor circuitries; maximized/optimized dielectric capacitance and strength; and increased capacitance (e.g., doubling and up to thirty-fold increase compared to previously-reported SEBS single layer dielectrics). Such a synaptic switch (transistor or transistor-based circuitry) may have one or more of the following attributes: mostly- or all-solid materials to make the synaptic switch to be less influenced by water or water solution; improved environmental stability compared to previously-reported devices; and high stretchability without using and/or without requiring any liquid or gel components to provide the stretchability attributes. In this manner, the stretchable high-k multi-layer dielectric is non-soluble in aqueous solution.

In connection with a more specific experimentally-based example embodiment, aspects of the present disclosure are directed to an apparatus (e.g., including a device, article and/or system) comprising or involving one of more of the following: (a) e-skin to provide sensory stimulation to the nervous system in a live being, which emulates the natural sensorimotor loop; (b) a tri-layer high-κ stretchable dielectric design which enables reduction of the driving voltage of stretchable circuits more than 10-fold and up to 60-fold (e.g., from 30 V to 0.5 V) for safe and energy-efficient on-body operation; (c) transistor arrays integrated with the stretchable dielectric design which exhibit one or a combination of any two or more of the following: predominant stretchability in a large range (e.g., up to 100% strain), increased or maximum mobility (e.g., 2.3 cm²V⁻¹ s⁻¹ (with 2.01 cm²V⁻¹ s⁻¹ on average), sub-threshold swing (SS) down to 85 mV per decade, and minimized power dissipation (e.g., 1.7 pJ for intrinsic power-delay product and 0.25 pW for static power consumption); (d) realization of an amplitude-decoupled frequency modulation in a widely tunable range (e.g., up to 80 Hz) using soft ring oscillators and edge detectors circuits for biomimetic perception (e.g., from a few to several (e.g., 5-12) pressure sensors and a few to several temperature sensors); and (e) the sensors being a solid-state (all-solid-state) stretchable synaptic transistor to convert frequency-encoded sensing amplitude signals back to corresponding current output levels for a closed-loop actuation of downstream body activities with stable operation (e.g., even in the aqueous physiological environment).

Consistent with the present disclosure, such devices and/or methods may be used for producing (among other examples disclosed herein) devices leveraging or benefiting from low-voltage driven soft electronics for wearable devices, and/or bio-interface and neuromorphic devices.

Consistent with another such exemplary aspect, the integrated constitution: forms or includes a neuromorphic e-skin system to emulate simultaneously closed-loop sensory encoding and mechanical softness of natural skin; and/or includes a monolithic e-skin or e-covering system with a plurality of flexible electronic components and is to emulate sensory feedback functions of a sensorimotor loop in biological skin. Further, the sensor can include a stretchable high-κ multi-layer dielectric (e.g., tri-layer or three or more layers) integrated with a low-voltage driven transistor-based circuit to provide a stretchable dielectric sensor design. In one example, a tri-layer high-permittivity (K) stretchable dielectric design facilitates a significant reduction of the driving voltage for the active circuitry (e.g., each transistor) of the stretchable circuits. In more specific examples, this low-level driving voltage is in a low-voltage range such as on the order of 1 V, and in certain instances in a range of 0.5 V to 1.5 V (e.g., down to 1 V) for safe and energy-efficient on-body operation.

Consistent with other exemplary aspects in this context, the sensor can include a stretchable ionic dielectric material, and the active circuitry includes an intrinsically-stretchable synaptic transistor that is characterized as being solid state and non-soluble in aqueous solution.

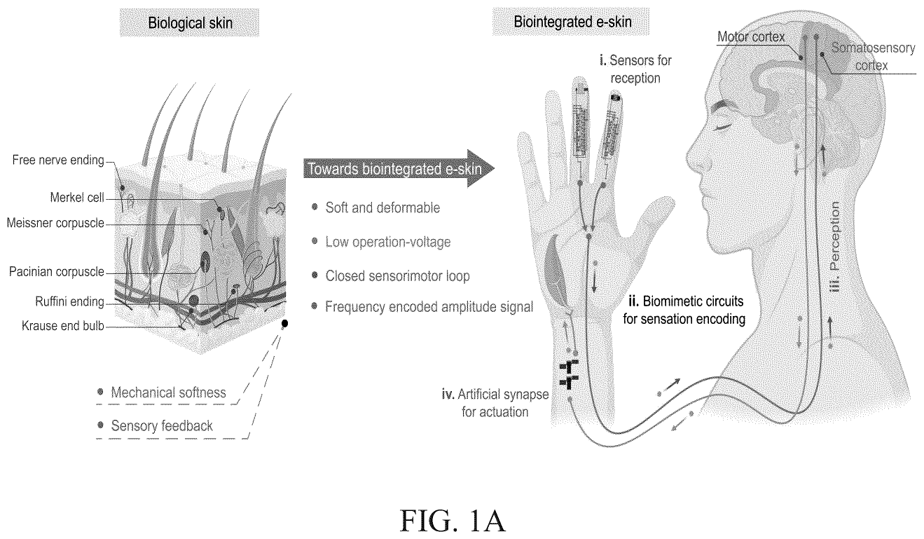

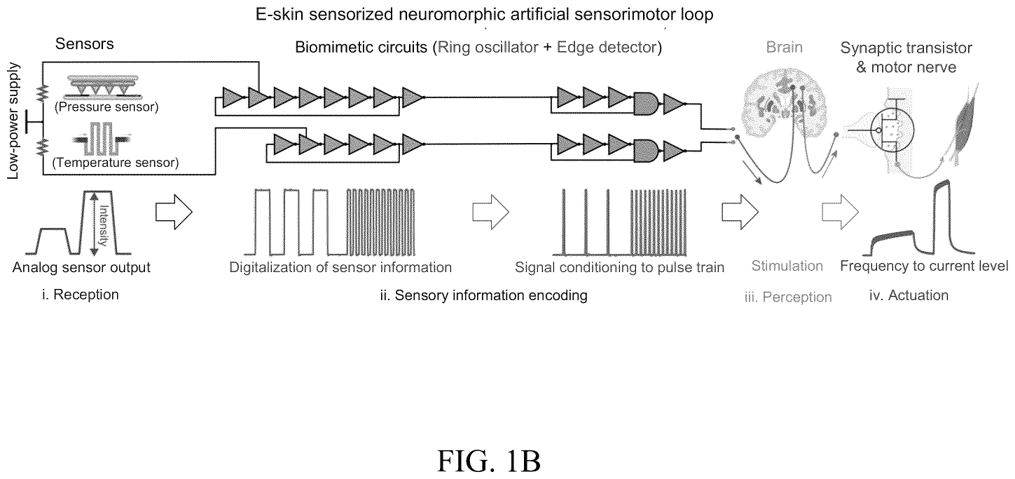

According to aspects of the present disclosure, it has been shown that the combination of sensory capabilities and mechanical softness of skin enables effortless perceptions and responses to various external stimuli, and also allows complex tasks to be performed in both dynamic and unstructured environments. This is largely shown, for example, through FIGS. 1A-1B and FIGS. 2A-2H. FIG. 1A is a diagram showing attributes and implementation aspects of an e-skin design including a synaptic transistor, according to certain exemplary embodiments of the present disclosure. FIG. 1B is a schematic showing overall flow and exemplary e-skin components implemented in certain example embodiments, consistent with the present disclosure. More particularly, FIG. 1B shows signal digitalization and conditioning circuits are configured to convert analog signals from sensors to spike-train signal patterns and artificial synapses to regulate current amplitude to trigger body movements.

Using such an example as in FIGS. 1A-1B, a monolithically integrated, soft, and low-voltage-driven e-skin system is readily developed primarily with soft and flexible (and/or without any rigid) electronic components for emulating the sensory feedback functions of biological skin, including multimodal reception, nerve-like pulse train signal conditioning, and closed-loop actuation.

FIGS. 2A-2G depict aspects and related parameters associated with a specific example, according to the present disclosure, involving low-voltage-driven high-performance stretchable organic transistors. In this specific example, the dielectric material is part of a tri-layer or multiple-layer structure (e.g., three or more layers) and the active (transistor) circuitry is implemented using solid-state synaptic transistor circuitry, with the structural integration being flexible and/or reversibly (e.g., intrinsically) stretchable.

FIG. 2A is a set of related diagrams, including a schematic and corresponding graphs, showing exemplary device structures with an inset depicting in part an integrated constitution of components, for operation for a certain example implementation consistent with the present disclosure. FIG. 2B is a related graph depicting dielectric constant versus frequency, according to certain exemplary aspects of the present disclosure. In these specific examples, reducing the driving voltage is associated with increasing the gate capacitance, which is benefited by a thin and high-dielectric constant layer as in the first (top) part of FIG. 2A. In a more specific example and among various commercially-available examples of dielectric elastomers, nitrile-butadiene rubber (NBR) was used in such experimentation according to the present disclosure. Unlike ionic polymer dielectrics that suffer from permittivity drop with increased frequency, NBR has a high permittivity (κ˜28), which is induced by polarization of nitrile groups and can be well maintained within a wide frequency range up to 10⁶ Hz (as in FIG. 2B).

FIGS. 2C, 2D and 2E illustrate, for a specific type of apparatus using NBR in accordance with the present disclosure. In connection with this specific type of apparatus and also according to the present disclosure, a direct photo-patterning method was developed with down to 2 μm (microns) via ultraviolet light-triggered azide-crosslinking reaction. The cross-linked NBR is solvent resistant, which is desirable for subsequent processing. However, the transistor transfer curve showed large hysteresis and low mobility (e.g., attributable to the energetic disorders at the semiconductor-dielectric interfaces induced by the highly polar nitrile groups). This phenomenon is known for other organic transistors with high-κ dielectrics. Such a trade-off between high κ-value and high-trap density makes it challenging to realize both low driving voltage and high carrier mobility in stretchable organic devices.

According to surprising results discovered in connection with experimental efforts leading to the present disclosure, specific examples address and overcome such challenges. These specific examples pertain to the previously-discussed stretchable multi-layer (e.g., tri-layer) dielectric stack as realized by passivating the layer of high-κ NBR, for example, by passivating with an ultra-thin non-polar poly SEBS elastomer coating (˜15 nm), followed by a hydrophobic OTS molecular modification coating (e.g., with a thickness optimized for specific application(s) as in the third part of FIG. 2A). This tri-layer dielectric stack, with a suitable surface energy, induces a desirable nano-confined morphology in the stretchable semiconductor layer, allowing for a high charge carrier mobility as shown in FIG. 2C. In addition, this approach offers a smooth surface with low trap density to decrease the charge carrier scattering. In certain specific examples, the smooth surface has an average roughness being less than 0.5 nm and in some instance, less than 0.2-0.3 nm, and in some instance about or as low as <0.17 nm. Therefore, compared to the single-layer NBR dielectric devices, the carrier mobility was boosted by around 50-fold with the multi-layer design (largely due to the NBR-SEBS aspects as in a bi- or tri-layer design), while maintaining the low driving voltage (FIG. 2C). To quantify the interfacial trap density, the activation energy was measured for charge transport (E_{A}) of various dielectric designs, and the combination of NBR-SEBS-OTS with directly spin-casted semiconductor shows the lowest E_{A} due to the optimal dielectric-semiconductor interface and semiconductor morphology, as shown in FIG. 2D.

Another benefit afforded by this type of tri-layer design is the significantly-enhanced dielectric strength under both direct and alternating voltage biasing, thus allowing the use of a thinner dielectric layer to further increase the gate capacitance. After the deposition of SEBS and OTS layers, a steady increase in the breakdown voltage was observed, indicating less pinholes as in FIG. 2E. The minimum thickness that can withstand 100% strain with a high yield in transistor arrays (>80%) is ˜300 nm (285 nm NBR plus 15 nm SEBS), whose capacitance value is 30-fold higher than the SEBS-only dielectric of 1.2 μm. Compared to other previously reported elastomeric dielectrics, this specific tri-layer design allows low operation voltage and high carrier mobility at the same time (FIG. 2F).

With good solvent resistance and patternability, this specific type of design with a high-κ multi-layer dielectric is a relatively important development for scalable and transfer-free fabrication of low-voltage-driven intrinsically stretchable transistor arrays such as shown in the second part of FIG. 2A. The resulting arrays showed stretchable transistor properties, including: 3 Volt (V) operation with on/off current ratio ˜6 orders of magnitude, negligible hysteresis (˜ 20 mV under 3 V operation), low gate leakage (˜10 pA), high mobility, high yield (generally ˜ 90%, maximum 100% for two batches of 50-transistor-array, see materials and method), high stretchability (up to 100% strain), and high cyclability (e.g., over 1000 stretch-release cycles under 60% strain as in the third part of FIG. 2A.

Compared to previously reported low-K stretchable dielectrics, for this example of the present disclosure transconductance normalized by channel width (Gₘ/W_{ch}) was improved by >10-fold (FIG. 2G). Moreover, a subthreshold swing (SS, 85 mV per decade) was achieved for stretchable transistors comparable to rigid polycrystalline Si (poly-Si) transistors (FIG. 2G). As a result, examples of the present disclosure involving stretchable transistor arrays showed high on/off current ratio at low gate voltage (4 orders of magnitude at 0.75 V). The improvements in the key figures-of-merit for the transistor performances (driving-voltage, SS, transconductance, on/off ratio and/or leakage current) allow soft transistors (implemented according to examples of the present disclosure) to operate with low power, which in some instance is a 1-2 orders of magnitude (e.g., ˜100-fold) less for both dynamic (1.7 pJ) and static (0.25 pW) power dissipations, compared to existing stretchable transistors (see, e.g., FIG. 2H). Also according to examples of the present disclosure, the operation of a stretchable functional circuit (e.g., pseudo-E inverter circuit) has been demonstrated, for example, with surprising results such as parameters including the driving voltage of ±0.5V under 100% strain, and a stretchable single-stage pseudo-D inverter circuit with a gain value as high as 120.

These benefits or/and advantages associated with specific examples of the present disclosure are shown by way of comparisons. FIG. 2E shows dielectric strength and breakdown voltage comparison between different kinds of elastomeric dielectrics and the exemplary type of tri-layer dielectric as discussed above in connection with the present disclosure. Also with reference to the exemplary type of tri-layer dielectric, whereas FIG. 2F shows a comparison of mobility and operational voltages for previously-reported transistors relative to this exemplary type of tri-layer dielectric as discussed above. FIGS. 2G and 2H show further comparisons involving previously-reported transistors relative to example embodiments according to the present disclosure.

Accordingly, the elastic transistor of FIG. 2A may be useful for a variety of different types of semiconductor transistors (including but not limited to those needing one of more of the above-disclosed benefits). Such an elastic semiconductor-type transistor may be more generally characterized as one which includes: a stretchable high-k dielectric layer (“high-k dielectric layer”), and at least one other stretchable dielectric layer integrated with the high-k dielectric layer into a single constitution having the high-k dielectric layer being between the gate of the elastic transistor and the at least one other stretchable dielectric layer, wherein k, representing “dielectric constant”, is not less than four (and in some examples not less than three). In this manner, the gate, source and drain of the elastic transistor are used with a stretchable high-k multi-layer dielectric to provide steady-state operation with electrons and/or holes flowing between the source and the drain in response to a low driving voltage (e.g., in a range of less than 30 V to 0.5 V).

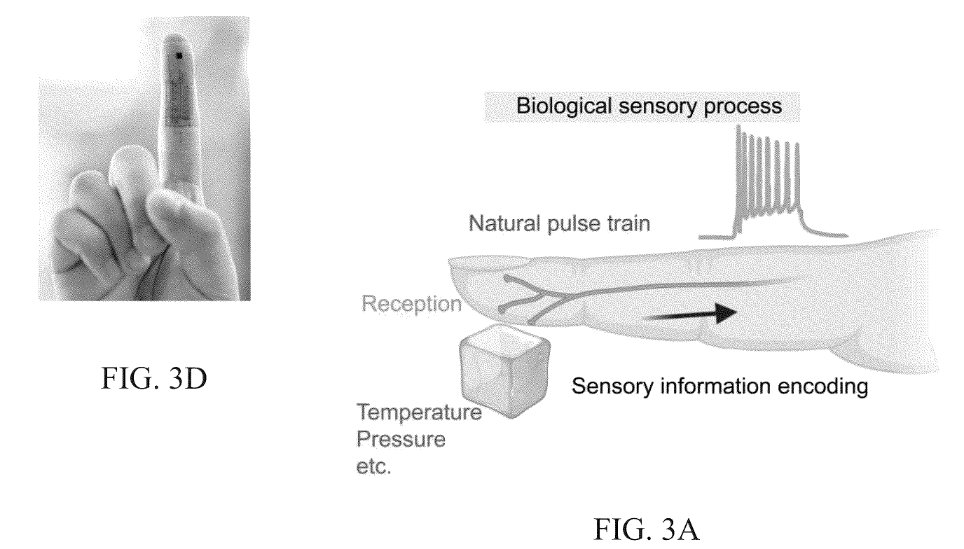

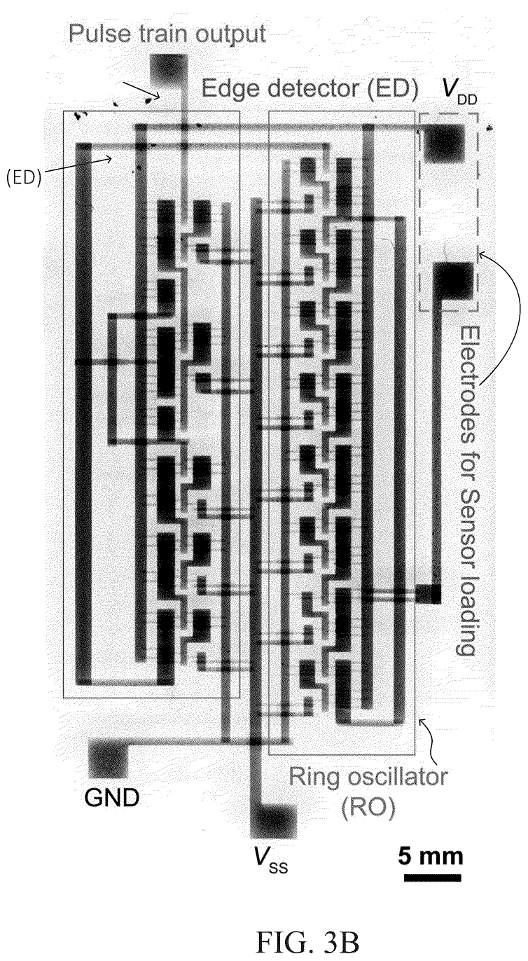

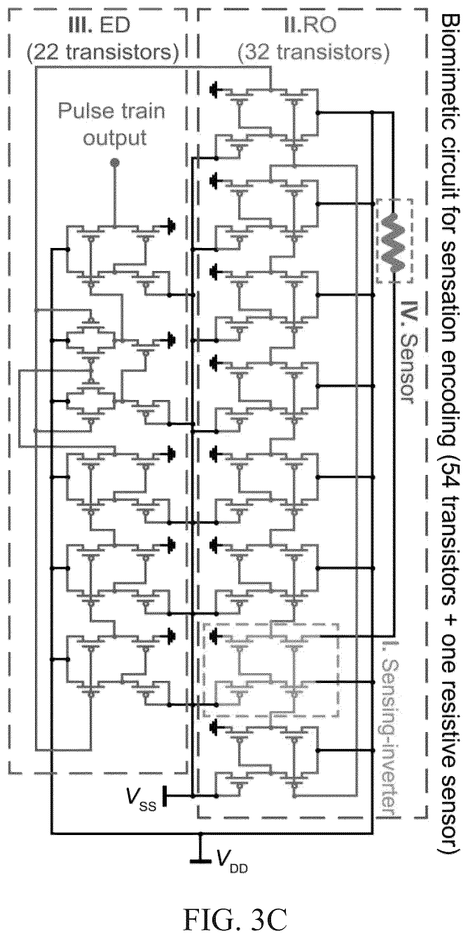

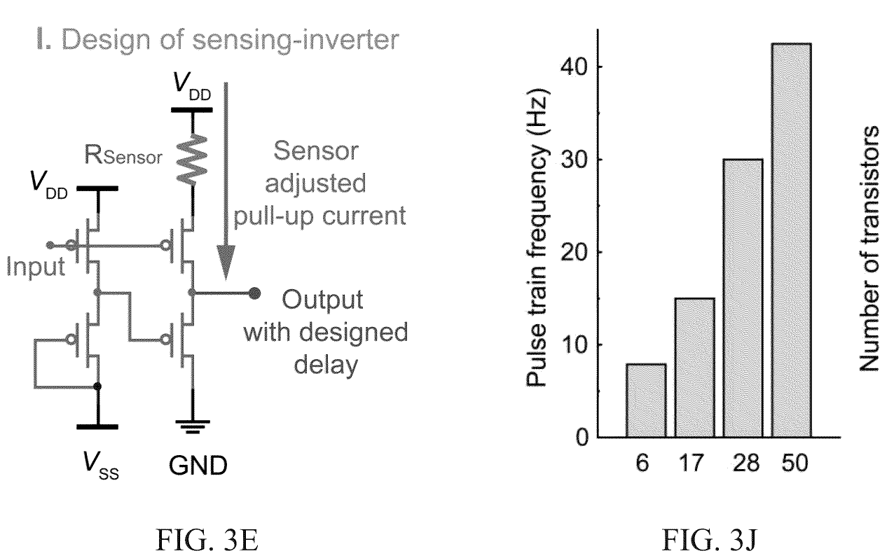

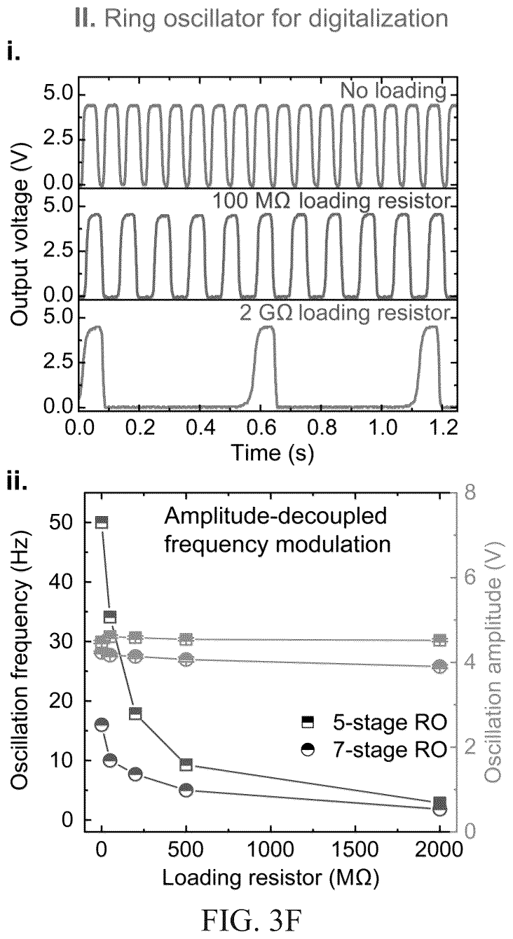

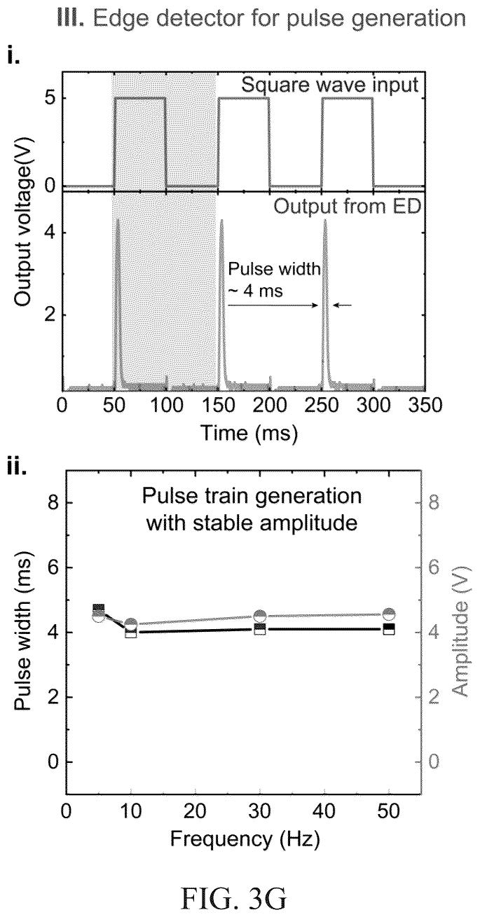

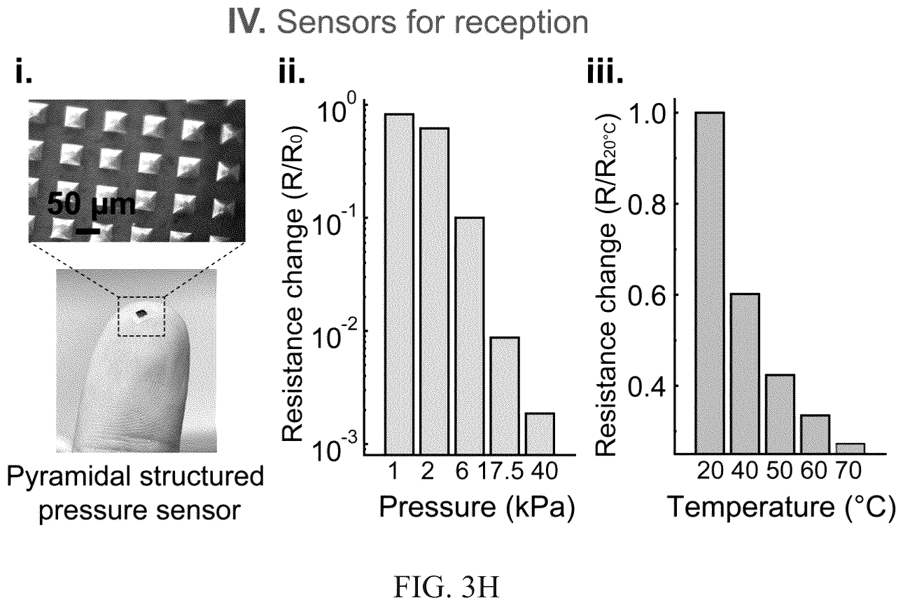

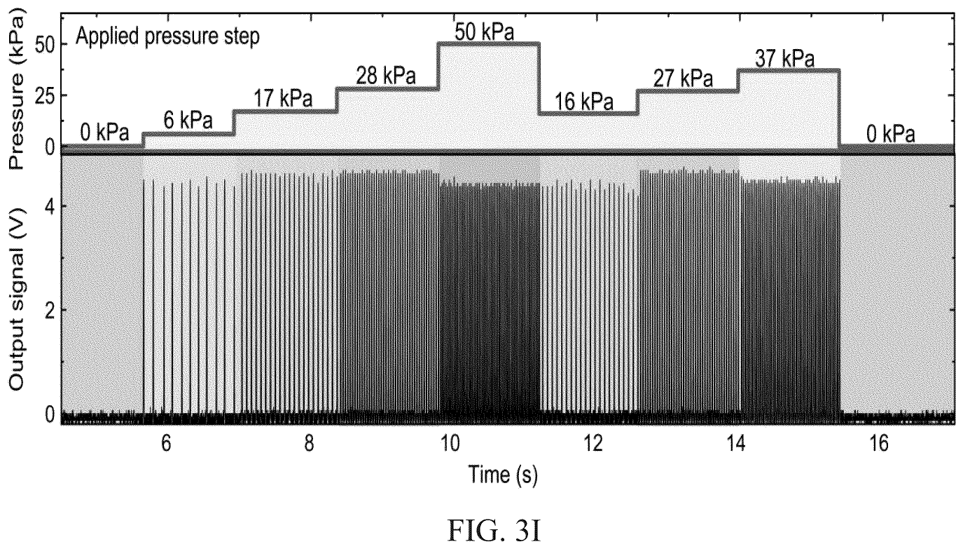

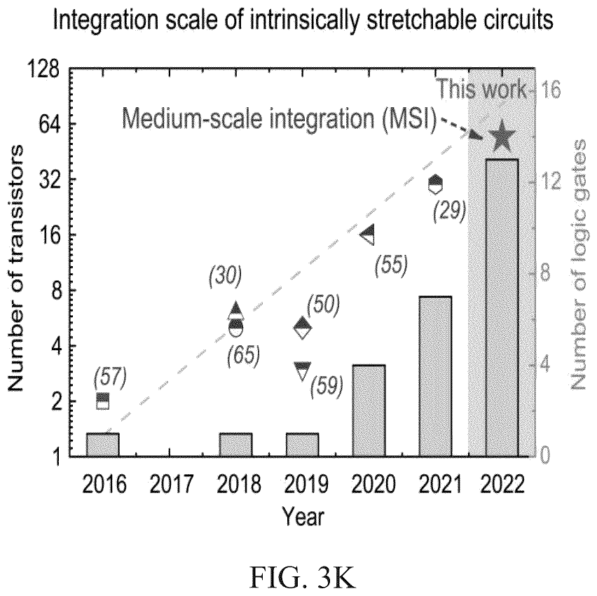

FIGS. 3A-3K, also consistent with the present disclosure, depict aspects concerning signal conditioning circuit system for nerve-like pulse train generation. FIG. 3A is a schematic diagram showing a natural perception process consistent with certain exemplary aspects of the present disclosure. For this system depicted in FIG. 3A and as an example of soft e-skin patch or cover material on a finger or digit, according to certain exemplary aspects of the present disclosure, FIG. 3B is a stretchable 7-stage ring oscillator and edge detector (RO-ED) circuit with reversibly stretchable and flexible transistors (shown via an optical microscopic image), and FIG. 3C is a transistor circuit diagram of the biomimetic sensor-circuit system for sensory information encoding (via 32 transistors for as a ring oscillator and 22 transistors as an edge detector). FIG. 3D is an image of a corresponding apparatus (e.g., soft e-skin with integrated constitution as such with sensory information coding) on finger.

With the optimal characteristics of individual transistors, the characteristics can be further integrated to make low-voltage functional circuits for direct on-skin operation and mimic the sensory functions of biological cutaneous receptors. During natural perception processes as depicted by the example of FIG. 3A, somatosensory receptors transform stimulus input amplitudes (reception phase) into frequency-modulated pulse trains with a constant amplitude (encoding phase) for efficient and high-fidelity signal transmission. Consistent with the example system shown by the schematic diagram of FIG. 3A, the natural perception process is recapitulated according to the present disclosure via a circuit system with sensors collecting external stimuli, ring oscillators (RO) for frequency modulation of sensor signals, and edge detectors (ED) for action-potential-like pulse train signal generation.

It is appreciated that previous sensor-RO frequency-modulation systems have involved inserting the sensor between stages of inverters and the power source (V_{DD}) to tune the effective V_{DD}, or between any two stages of inverters in the loop to introduce an additional resistor-capacitor (RC) delay. However, both methods introduce large variations in the oscillation amplitudes with limited dynamic range for frequency tuning. On the other hand, frequency modulations in biological systems are amplitude decoupled, and generally ranging from 0 to 100 Hz. Certain examples of the present disclosure are useful to address this issue, by placing an appropriate sensor into the second stage of the inverter (termed ‘sensing-inverter’). FIG. 3E shows a circuit diagram and working mechanism of such a sensing-inverter design. Based on the circuit modeling, the pull-up charging current of the sensing-inverter can be effectively adjusted by the sensor response, while the operation of other stages is unaltered. Additionally, benefiting from the direct charging from V_{DD}, the output of the sensing-inverter can maintain a large swing over 2.9 V even with a loading resistor of 1 GΩ (only 0.2 V for RC delay one with a 100 MΩ resistor). Thus, the large output signal from the sensing-inverter can be gradually amplified by the following stages and stabilized around V_{DD} at the final RO output terminal, regardless of the sensor response. Furthermore, the combination of the large changes for the pull-up current and the unattenuated voltage amplitude enabled a wide dynamic range of frequency change based on sensor value. Experimentally, benefitting from exemplary designs according to examples of the present disclosure and from the high on/off current ratios of transistors consistent herewith, these experimental efforts successfully realized a modulation frequency range that is relevant for physiological signals (i.e., 0 to 100 Hz) (36), along with stable oscillation amplitude when the loading resistance changes (i.e. sensor response) between 0 and 5 GΩ.

For such a soft pressure sensor, FIG. 3F (i) shows transfer curves with the amplitude-decoupled frequency modulation of a 7-stage RO with different loading resistor values. The RO output frequency changed from 16 Hz at 0 Ω to 1.8 Hz at 2 GΩ. FIG. 3F (ii) shows a graph with oscillation frequencies and amplitude of a 5- and a 7-stage ROs, while loading different resistors. Related experimentation led to the realization that the amplitude-decoupled frequency modulation property could be well maintained even under 100% strain. Finally, to implement the multimodal sensory capability, both five- and seven-stage ROs were fabricated in certain examples of the present disclosure with different oscillation frequency ranges that can be used to distinguish information from multiple sensors. The output waveforms of RO alone would have a wide pulse duration with stage-dependent variations, which are different from natural action potentials with transient spikes and fixed narrow pulse widths.

FIG. 3G, including parts (i) and (ii), is a set of graphs respectively reflecting parameters associated with an edge detector used to generate pulses (as pulse trains) in connection with certain exemplary aspects for examples consistent with the present disclosure. Using ED circuits developed according an example of the present disclosure, the RO output signals were effectively reshaped. Utilizing a properly designed delay network and an AND gate, the ED can effectively capture the rising edges of the incoming signals to generate sharp pulses as in FIGS. 3G (i) and 3G (ii) which shows two different delay network designs respectively as RC network and inverter chain.

More particularly, FIG. 3G (i) shows input (top) and output (bottom) signals from an ED showing a pulse width ˜4 ms (milliseconds), and FIG. 3G (ii) shows pulse width and amplitude of an ED under different input signal frequencies (with a square wave, amplitude signal input at 5 V, 50% duty cycle). It was observed that the 3-stage inverter chain-based ED showed stable output amplitude under different input frequencies, while the RC network-based ED showed decreased output amplitudes with higher frequencies of the input signals, which is due to the roll-off behavior of the RC network. With the optimal geometry design of the delay-network, the AND gate, and corresponding circuit fabrication, the stretchable ED was realized in examples of the present disclosure for enabling generation of stable pulse signals with a duration of ˜4 ms and an amplitude of ˜5 V with different frequencies of square wave input (1 Hz, 10 Hz and 50 Hz). This pulse width can be independently tuned through the stage number of the inverter chain or transistor size. Notably, with a proper geometry design, example ED-based example of the present disclosure can capture the rising edges of sinusoidal signals as well, making it possible to reshape the outputs from ROs with high oscillation frequencies that are unable to generate square-wave-like signals. The function for stretchable ED examples of the present disclosure can be well maintained up to 100% strain with minimal increase of the pulse width. Notably, pulses generated by piezoelectric, triboelectric, or ionic sensors are only due to repetitive pressing. These devices are not yet capable in encoding amplitude information to frequency. They also cannot properly tune the pulse duration and amplitude without signal conditioning circuits.

With all the appropriate components identified and/or developed, one experimental effort involving fabricated a monolithic integrated electronic skin patch that could be as soft as human skin modulus to emulate the processes of nature sensation with a driving voltage less than ±5 V (FIGS. 3B and C). By loading standard resistors ranging from 10 MΩ to 5 GΩ (to mimic the sensing response range), the frequencies of the output pulse train signals are modulated from 31 Hz to 1 Hz for a 7-stage RO-based system, 42 Hz to 2 Hz for a 5-stage one. Besides the steady inputs, e-skin examples of the present disclosure can perceive simulated vibration stimuli up to 20 Hz. Benefiting from the low subthreshold swing value and high mobility, this neuromorphic circuit can successfully output pulse train signals with various frequencies, driven by ±0.75 V.

Furthermore, carbon nanotube (CNT) based stretchable pressure sensor with three-dimension pyramidal structures, as well as thin film temperature sensors, were developed and integrated into the system to mimic natural mechanoreceptors and thermo-receptors, respectively. This is shown in multiple aspects of FIG. 3H as a set of graphs showing parameters for an edge detector with pulse generation and showing a set of input and output signal in the first graph and summarized results in the second graph, according to certain exemplary aspects of the present disclosure. More particularly, FIG. 3H includes: (i) a photo showing a pressure sensor with pyramidal structures, and the graphs bar plot changes under stimuli in terms of resistance for a pressure sensor (ii) and of temperature (iii).

When applying pressure from 0 to 50 kPa or changing temperature from 22° C. to 90° C., pulse train signals were generated and fired faster in response to the pressure and temperature stimulus levels (FIGS. 3I AND 3J). This is shown in FIGS. 3I and 3J, with FIG. 3I showing a pulse train output (bottom) from a pressure sensor-RO-ED (5-stage) system during a pressing-releasing cycle (top), and FIG. 3J showing an output frequency of the sensor-RO-ED system under different pressures of data shown in (FIG. 3I). The above e-skin circuit example includes 54 stretchable transistors realized medium-scale integration for stretchable organic electronics. Moreover, multimodal perception was implemented through dividing the pulse train signals of different stimuli into distinct frequency regimes. When continuously biased under±5 V in ambient, the system was observed to remain functional after 8 hours.

FIG. 3(K) shows a comparison of previously reported intrinsically stretchable circuits with the above type of RO-ED circuit (according to certain exemplary aspects of the present disclosure including FIG. 3A showing the natural perception process) and in terms of the integration scale level (number of transistors and logic gates). All circuits were operated under V_{DD}=5 V and V_{SS}=−5 V.

FIG. 3K is a graph showing comparisons involving previously reported circuits relative to example embodiments. The numbers shown within parentheses in the graph of FIG. 3K correspond with previously-reported citations provided in Appendix A of the above-referenced U.S. Provisional Application.

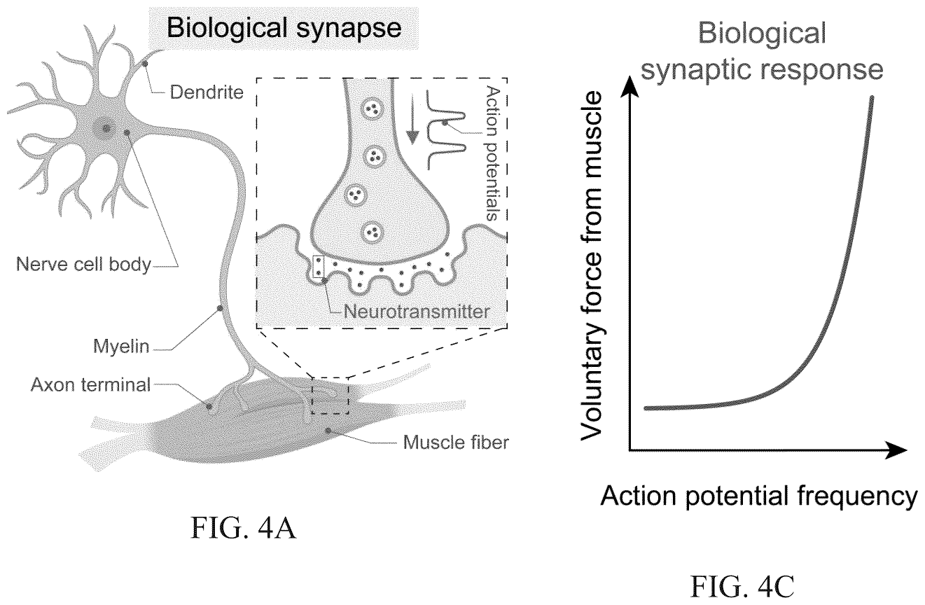

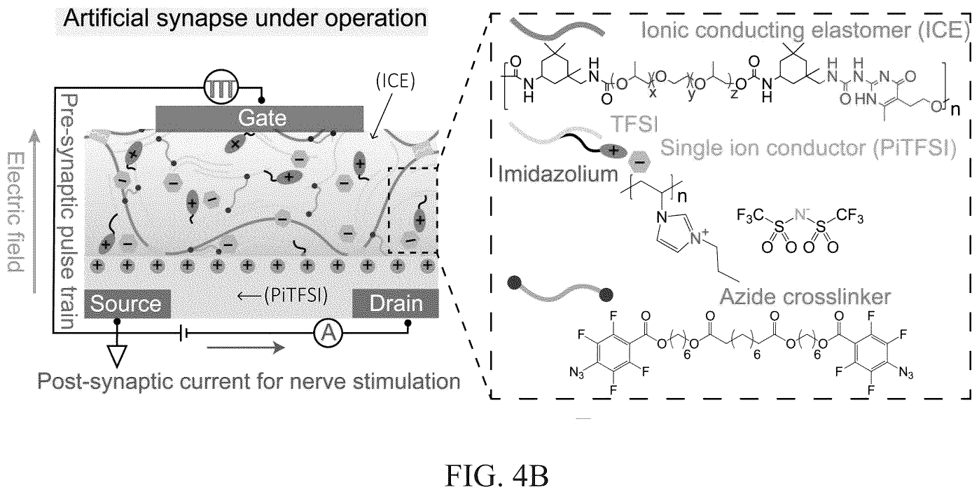

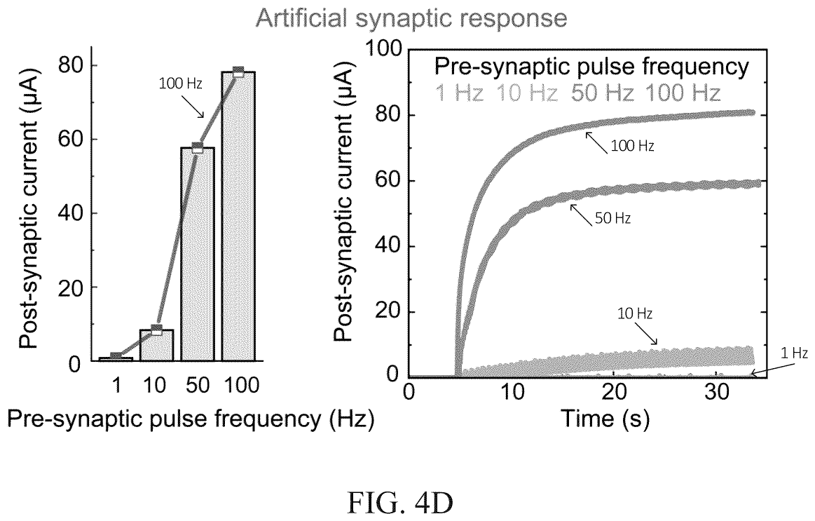

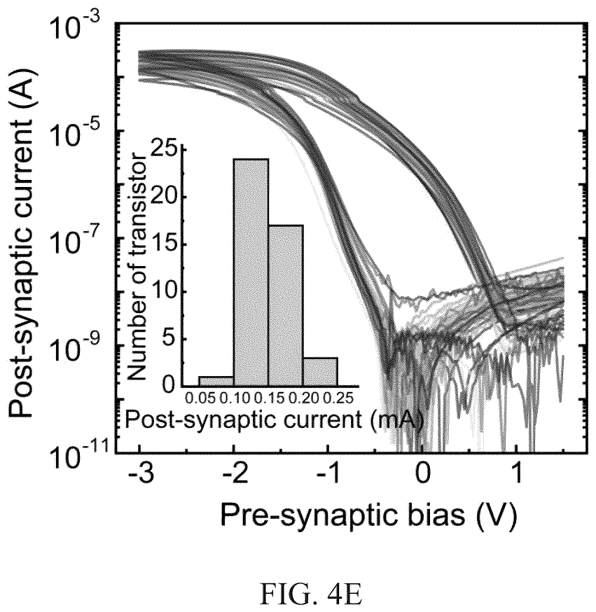

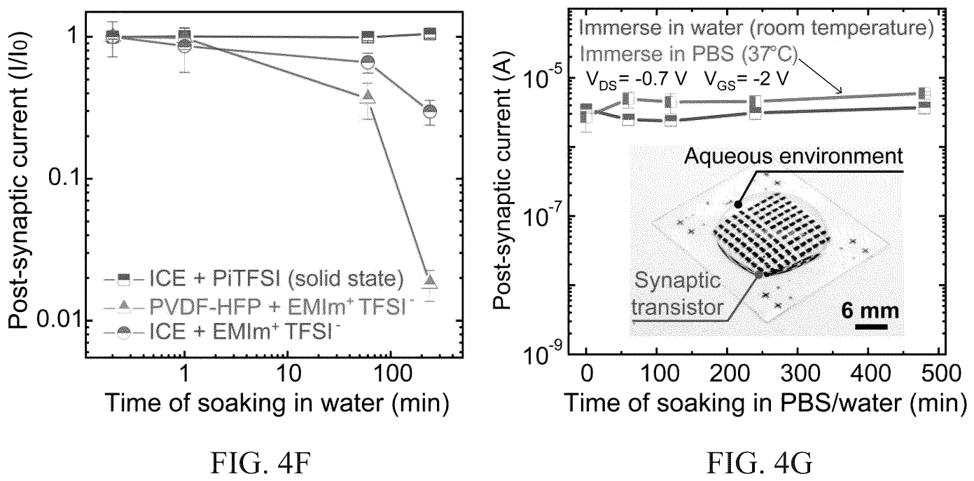

FIGS. 4A-4G are also consistent with aspects of the present disclosure, and they involve aspects concerning a solid-state synaptic transistor-based circuit involving artificial synapses to trigger downstream actuations. Before delving into FIGS. 4A-4G, it should be appreciated that a characteristic of a natural sensory feedback loop is bi-directional signal communication between perception and actuation. To complete the sensorimotor loop, besides the soft e-skin system for sensation, discussion next turns to passing the frequency-encoded sensor information to the central nervous system and to actuate downstream muscle responses based on the input stimulus. One challenge is to translate appropriately the frequency-modulated signals to various levels of body movements. FIGS. 4A, 4B and 4C are useful to illustrate this challenge. FIGS. 4A and 4B show respective comparisons of the working mechanisms between a biological synapse and an artificial synaptic transistor, and material designs and selections of artificial synapse examples of the present disclosure are shown in the inset (dashed box) of FIG. 4B. Components of the biological synapse are labeled as also shown therein, and in biological synapse (as shown in FIG. 4C), larger muscle forces (output amplitude) could be generated when action potentials with higher frequencies are transmitted through the motor nerve.

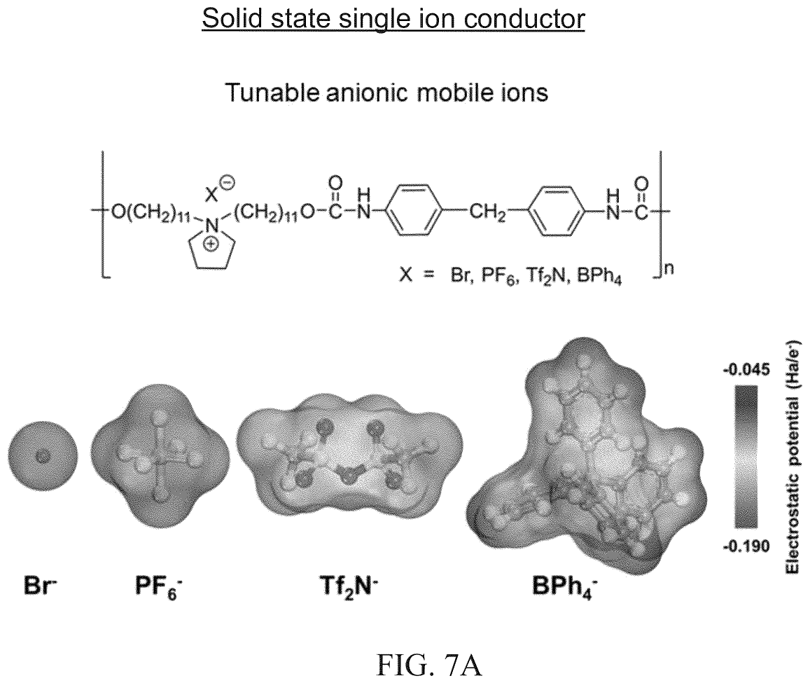

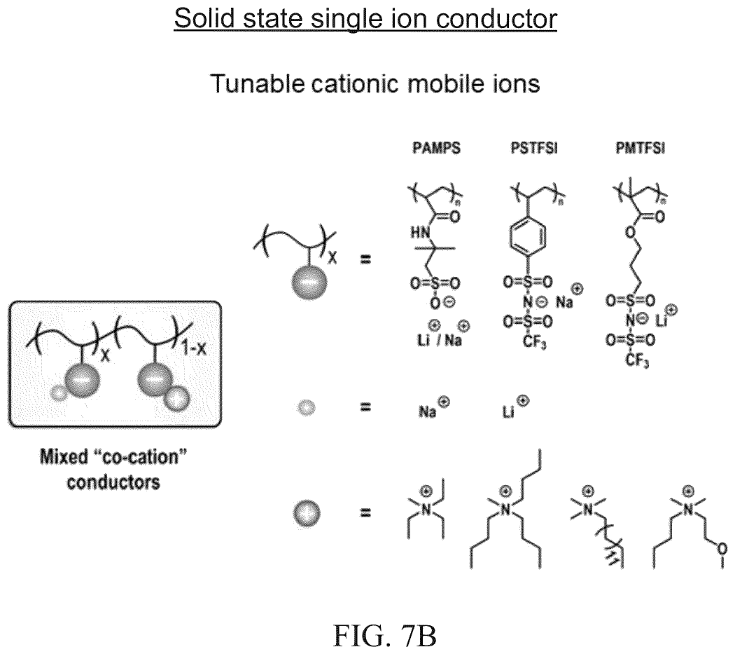

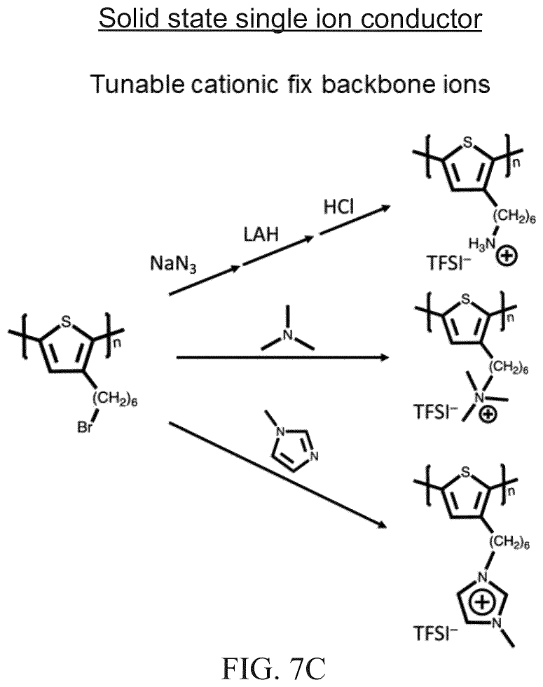

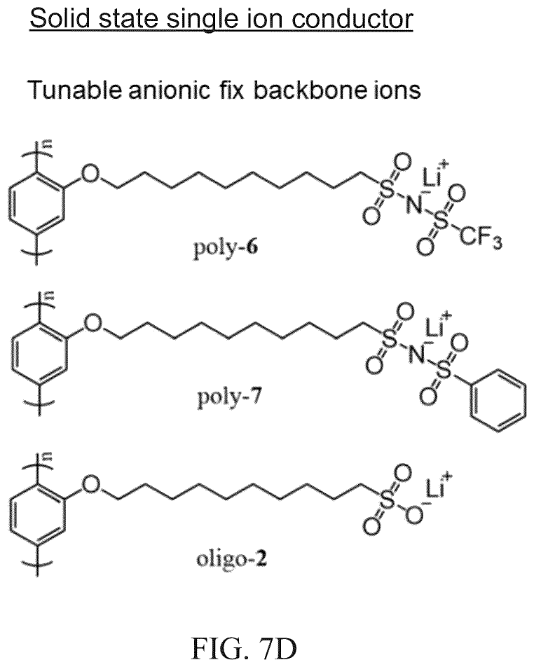

More particularly, FIG. 4B shows an artificial synapse via a synaptic transistor and ionic conductive elastomer (ICE) implemented as an integrated constitution. In this example, a single ion conductor and ionic conductive elastomer are chosen for the solidity and the stretchability attributes. The entire device of the illustration is built from soft and stretchable materials. As particularly useful in connection with a synaptic transistor, specific examples of the present disclosure involve synaptic transistors being based on ionic gating because of their similar working mechanism as biological synapses (see, e.g., FIG. 4B). Moreover and as shown in FIG. 4D, there is a correlation between pre-synaptic pulse train frequency and post-synaptic current amplitude from a synaptic transistor. When gated by pulse train signals (i.e., mimicking action potentials), mobile ions (e.g., mimicking neurotransmitters) will migrate to the dielectric-semiconductor interface and induce a conducting channel. Higher frequency (together with higher duty cycle) would lead to higher post-synaptic current amplitudes. Previously-reported synaptic transistors are based on liquid/gel components with poor environmental stabilities or they use rigid materials with limited tissue conformability. Certain of the above-noted specific examples of the present disclosure overcome these issues through the use of an all-solid-state ionic dielectric developed by blending a previously-designed ionic conducting elastomer (ICE) with a high ion conductivity and a single ion conductor. As a single-ion conductor with a border interface region characterized as polycation interface in this example of FIG. 4B, an imidazolium-based polymer has the cation (or anion in other examples) fixed or tethered to the polymer for the single ion conduction. FIG. 4B and its inset exemplify use of PiTFSI which is one example of a single ion conductor in the form of a polyelectrolyte (e.g., poly (1-vinyl-3-propyl-imidazolium)bis(trifluoro-methanesulfonyl)imide). See also FIGS. 7A-7D for other examples of solid state single ion conductors which may be used similarly in alternative embodiments. Compared to previous reports using small molecule ionic species that suffered from dissolution in biofluids, according to examples of the present disclosure, a polyelectrolyte can be stably fixed in the elastomeric matrix. Using azide cross-linkers in examples of the present disclosure, this ionic dielectric was patterned and fabricated for an all-solid-state stretchable synaptic transistor array with good uniformity. FIG. 4E is a plot of transfer curves and post-synaptic current distribution (insert) of a synaptic transistor array, according to specific examples of the present disclosure with the transistors having a channel length/width of about 80/320 μm and a dielectric thickness of about 2 μm.

The above-characterized synaptic behavior was observed to maintain the large hysteresis window from the transfer curves under 50% strain. Notably, when pre-synaptic pulses with different frequencies were used as gate inputs to the synaptic transistor, large changes were observed in the amplitudes of post-synaptic currents, i.e., ˜4 orders of magnitude output difference between 1 Hz and 100 Hz inputs and ˜7 orders of magnitude when extending to 800 Hz (FIG. 4D). This is an important feature necessary to use frequency-encoded pressure amplitude information to generate different levels of body movements through the amplitudes of post-synaptic currents.

Furthermore, various experiments demonstrated stability success after soaking the device in physiological (e.g., water or water-based) fluids for different periods of time (e.g., 0.5 hour to over 4 hours), as indicated by the all-solid-state and being non-soluble in aqueous solution. Certain artificial synapse experiments, according to examples of the present disclosure. show less than 5% decrease in post-synaptic current, with no parts of the device dissolving, post-synaptic current decreases by less than 30% after soaking for 1 hour (versus certain examples containing small molecular ionic liquid losing ˜98.2% of the output current). These aspects are shown in connection with FIGS. 4F and 4G. FIG. 4F shows a comparison of water stability between different dielectrics. Ionic conducting elastomer (ICE) plus polyelectrolyte (PiTFSI) shows stable device performance after 4 hours immersion in water. 4 transistors were monitored and averaged. PVDF-HFP, poly(vinylidene fluoride-co-hexafluoropropylene); EMIm TFSI, 1-Ethyl-3-methylimidazolium bis(trifluoromethylsulfonyl)imide. FIG. 4G shows stability via testing averaged from 4 monitored synaptic transistors by soaking in water or 37° C. PBS solution up to 8 hours. The insert in the graph of FIG. 4G is a photo showing a stretchable synaptic transistor array immersed in aqueous environment. All error bars represent standard deviations. Post-synaptic currents were obtained from peak-current of either pulse gated results or transfer curve at the highest pre-synaptic bias voltage.

Accordingly, the elastic transistor of FIG. 4B may be useful for a variety of different types of transistors, such as those needing to tolerate stable operation while submerged in liquid. Whether or not the elastic transistor of FIG. 4B is a synaptic transistor (e.g., with one stretchable high-k dielectric layer including a single ion conductor and an ionic conductive elastomer (e.g., for providing a border interface region characterized as one of a polycation interface and a polyanion interface), and another stretchable dielectric layer corresponding to an interfacial portion along a border of the high-k dielectric layer), such an elastic transistor may be more generally characterized as one which includes: a stretchable high-k dielectric layer (“high-k dielectric layer”), and at least one other stretchable dielectric layer integrated with the high-k dielectric layer into a single constitution having the high-k dielectric layer being between the gate of the elastic transistor and the at least one other stretchable dielectric layer, wherein k, representing “dielectric constant”, is not less than four. In this manner, the gate, source and drain of the elastic transistor are used with a stretchable high-k multi-layer dielectric to provide stable operation with electrons flowing between the source and the drain in response to a low driving voltage (e.g., in a range of less than 30 V to 0.5 V. In this example of FIG. 4B, only electrons are flowing since its interface portion has cations fixed thereto, whereas another example with different chemistry (see, e.g., FIG. 7B) only holes are flowing since its interface portion has anions fixed thereto.

Consistent with the synaptic transistor of FIG. 4B as a second type of transistor and the semiconductor transistor of FIG. 2A as a first type of transistor, it can be seen that each of these transistor types provide a stretchable high-k multi-layer dielectric that in response to such low-driving voltages as discussed above. The stretchable layers include: a high-k dielectric layer, and another dielectric layer, with the high-k dielectric layer being between the gate of the elastic transistor and the other dielectric layer. In more specific examples,

An elastic synaptic-type transistor (e.g., general structure exemplified by FIG. 4B), can be implemented with one or more of a variety of aspects according to the present disclosure. In such examples: the stretchable high-k dielectric layer includes a single ion conductor, and said at least one other stretchable dielectric layer corresponds to an interfacial portion facing away from the gate, being along an outer border of the stretchable high-k dielectric layer with a thickness of not greater than several atomic layers (or not more than 20 nm), and having ionic conducting material to which one polarized-type of ion, as a anion or cation, is fixed; the transistor manifests a carrier mobility of greater than 0.5 cm²/V-per-sec. and/or occurs while the apparatus is submerged in an aqueous solution for at least an hour.

In certain more-specific examples of the present disclosure, these two transistor types are characterized as above (e.g., FIG. 2A and FIG. 4B), for example with the first type of (e.g., semiconductor) transistor and the second type (e.g., synaptic) transistor used in combination, as one of many examples, with the first (semiconductor) type being part of a logic circuit to process or amplify signals that drive, or respond to, signals coupled to the first type (e.g., sensor circuitry including the synaptic transistor). In the synaptic transistor, its stretchable high-k dielectric layer uses a single ion conductor (e.g., with a border interface region characterized as one of a polycation interface and a polyanion interface) and its other stretchable dielectric layer corresponds to an interfacial portion along an outer border of the stretchable high-k dielectric layer (e.g., as a blend of the high-k dielectric layer and adjacent substrate material, and/or as indicated previously). For the semiconductor transistor, its stretchable high-k multi-layer dielectric may use a nitrile-based synthetic in the stretchable high-k dielectric layer and an ultra-thin a low-k dielectric for its other stretchable dielectric layer. In this context, more specific semiconductor-transistor examples implement the stretchable high-k multi-layer dielectric using one of the multi-layer embodiments (e.g., tri-layer as discussed in connection with FIG. 2A, FIGS. 6A-6F) and, similarly, more specific synaptic-transistor examples implement the stretchable high-k multi-layer dielectric using one of the embodiments discussed in connection with FIG. 4B, FIG. 7A-7D.

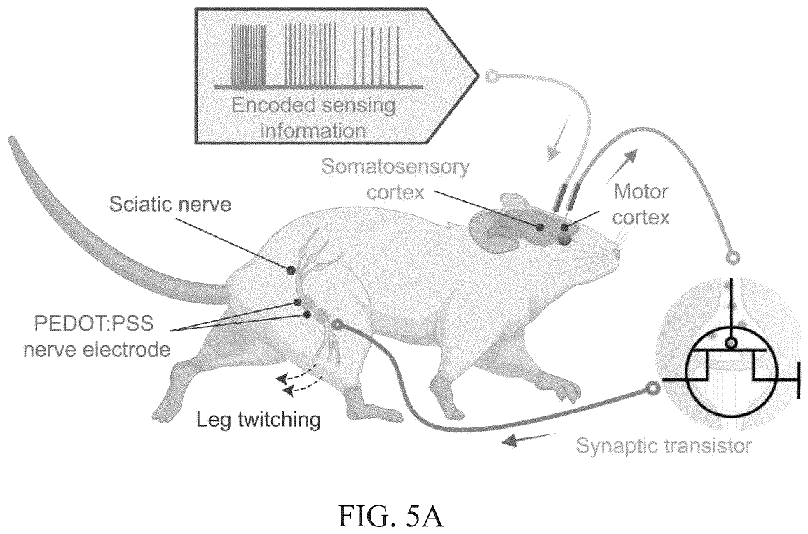

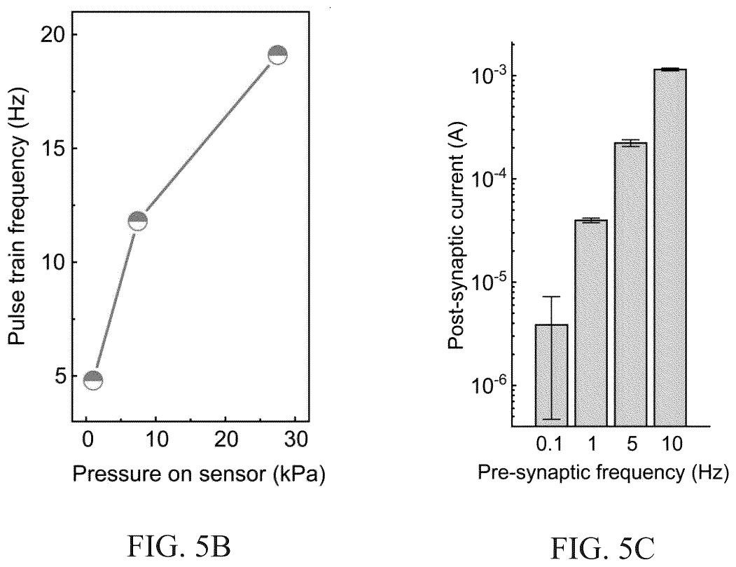

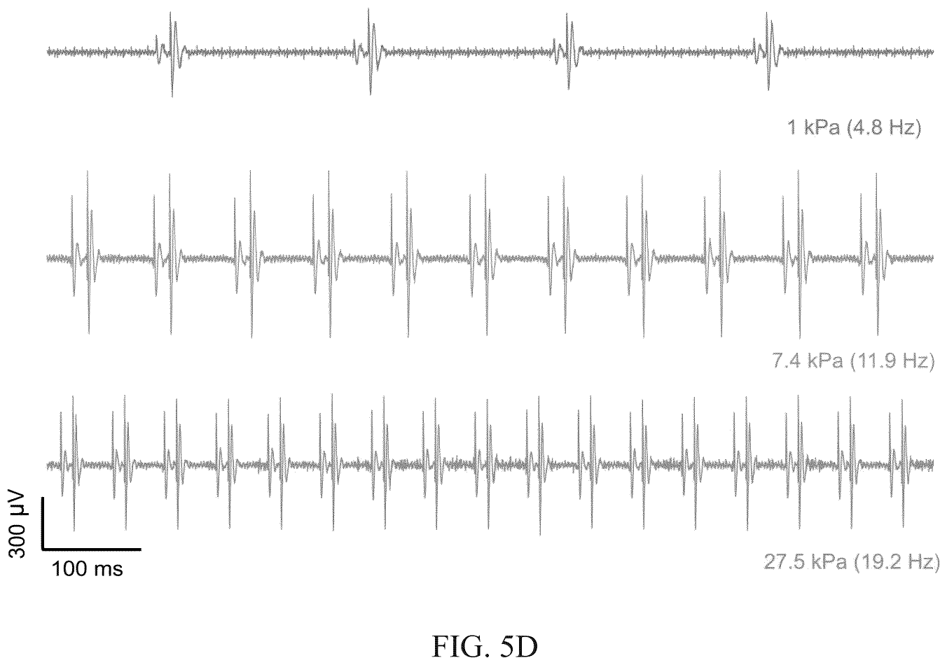

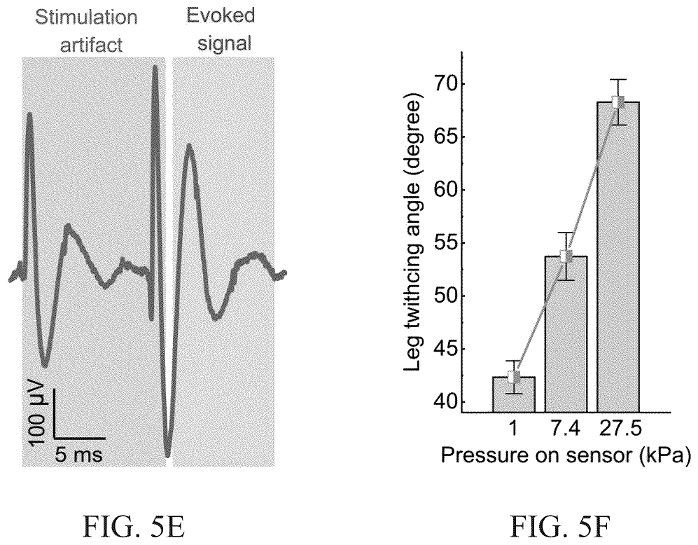

Further consistent with aspects of the present disclosure, FIGS. 5A-5F depict aspects of demonstrative sensorimotor loop with monolithic soft e-skin. For example, with most all, or all components in the e-skin system reproducing the biological perception-actuation loop, exemplary e-skin systems were successfully tested. The schematic diagram of FIG. 5A shows the structure of the artificial sensorimotor system. A pressure sensor-RO-ED system was used to translate the applied force into pulse train signal (as in the graph of FIG. 5B) for somatosensory cortex and evoke neuronal firings at the motor cortex, with the pulse train output frequencies under different pressure levels applied on pressure sensor, and data points obtained from one RO-ED circuit. The processed neural signals recorded from the motor cortex were used as the gate input of the synaptic transistor, leading to different post-synaptic currents for hind-limb controls (e.g., using PEDOT: PSS, poly(3,4-ethylenedioxythiophene): polystyrene sulfonate). FIG. 5C shows synaptic transistor current output biasing by different gating signal frequencies. Synaptic transistor channel length: 100 μm; channel width 2000 μm. Three synaptic transistors from the same batch were monitored.

The testing, based on such a platform in a live rat model as shown in FIGS. 5A-5C, included connecting the developed soft e-skin to the rat somatosensory cortex to emulate skin sensation (e.g., since it is expected to trigger feedback responses at the motor cortex). Evoked motor signals were then passed through the artificial synapse to stimulate the sciatic nerve for downstream muscle actuation, thus completing the artificial sensorimotor loop.

Experimentally, when the sensor was subject to forces of different magnitudes, the digitalized inputs for the somatosensory cortex successfully evoked neuronal firings at the motor cortex. These aspects are shown in FIGS. 5D and 5E. More specifically, these signals show recorded signals from the motor cortex corresponding to different sensor values. Stimulation artifact refers to the abrupt changes of signals during the span of electrical stimulation. It is not a real biological response, but from rapid saturation of the amplifier. Evoked signal is the real electrophysiological signal from the neuron being activated after the electrical stimulation.

After further amplification, with the recorded neural signals serving as the gate input of the synaptic transistor, the amplitudes of the post-synaptic currents were found to scale with applied pressure. The synaptic channel was interfaced with the sciatic nerve through a low-impedance poly(3,4-ethylenedioxythiophene): polystyrene sulfonate (PEDOT: PSS) electrode, resulting in the contraction of the biceps femoris muscle.

Similar to the natural sensory feedback process that would have more intense reactions to stronger force stimuli, the example bidirectional e-skin system, according to the present disclosure, also gave larger leg twitching angles with respect to the increased pressure inputs. As shown in FIG. 5F, these responses correlate in terms of angles of a leg in response to the different pressure inputs. More specifically and using a representative animal model, FIG. 5F shows correlation between twitching angle (of the animal's leg at the hip) at degrees of 44.6, 53.9 and 70.2, for respective amounts of applied pressure of 1 kPa, 7.4 kPa and 27.5 kPa. Data points represent average value from 4 rats. All error bars refer to standard deviations. This experimentation and resultant data demonstrates the feasibility of artificial e-skin for neuroprosthetics. This e-skin patch was attached on rat skin over 30 h, no skin irritation was observed. In summary, through rational material design and device engineering, a monolithically integrated soft e-skin system is achieved without rigid electronic components, featuring low driving-voltage, high circuit complexity, and biomimetic sensory feedback functions. Each of the exemplary neuromorphic systems of the present disclosure combines most, and in some examples all, such desired electrical and mechanical features of skin in one single device platform. This advance will aid to further next-generation prosthetic skins, human-machine interfaces and neurorobotics.

Accordingly, many different types of processes and devices using combinations of various ones of the above-discussed circuit-based and material-based design attributes may be advantaged by such aspects, the above aspects and examples as well as others (including the related examples in the above-identified U.S. Provisional Application).

It is recognized and appreciated that as specific examples, the above-characterized figures and discussion are provided to help illustrate certain aspects (and advantages in some instances) which may be used in the manufacture of such structures and devices. These structures and devices include the exemplary structures and devices described in connection with each of the figures as well as other devices, as each such described embodiment has one or more related aspects which may be modified and/or combined with the other such devices and examples as described hereinabove may also be found in the Appendices of the above-referenced Provisional Application.

As examples, the Specification, which includes the appendices of the underlying U.S. provisional application, describes and/or illustrates aspects useful for implementing the claimed disclosure by way of various circuits or circuitry, and which may be illustrated as or using terms such as materials and/or material-based layers, blocks, modules, device, system, unit, controller, and/or other circuit-type depictions. Such circuits or circuitry are used together with other elements to exemplify how certain embodiments may be carried out in the form or structures, steps, functions, operations, activities, etc. For example, in certain of the above-discussed embodiments, one or more modules are discrete logic circuits or programmable logic circuits configured and arranged for implementing these operations/activities, as may be carried out in such approaches discussed or illustrated in connection with the figures and/or slides disclosed in connection with more-detailed and/or experimental laboratory-type examples and performance criteria as presented in the above-referenced U.S. Provisional (e.g., as in one or both of Appendix A and Appendix B).

Further, unless otherwise indicated ranges (of any, and all metrics) are merely exemplary of “approximate ranges” wherein this term may be understood to vary the bound(s) of the range (e.g., using improved and/or degraded material- or circuit-based design parameters) by a degree of anywhere from 10-to-20 percent (or in some instances) from 5-35 percent, and, in the context of comparison to an improvement over a previously-reported effort, or general use of terms such as “approximate” or “about”, by a degree of improvement of 20 percent or greater, and as indicated for some relevant parameters by at least one order of magnitude.

Based upon the above discussion and illustrations, those skilled in the art will readily recognize that various modifications and changes may be made to the various embodiments without strictly following the exemplary embodiments and applications illustrated and described herein. For example, methods as exemplified in the Figures may involve steps carried out in various orders, with one or more aspects of the embodiments herein retained, or may involve fewer or more steps. Such modifications do not depart from the true spirit and scope of various aspects of the disclosure, including aspects set forth in the claims.

What is claimed is:

1. An apparatus comprising:
an elastic transistor including a gate, a source and a drain, and a stretchable high-k multi-layer dielectric, to provide stable or steady-state operation with at least one of electrons and holes flowing between the source and the drain in response to a driving voltage, the stretchable high-k multi-layer dielectric including
a stretchable high-k dielectric layer (“high-k dielectric layer”), and
at least one other stretchable dielectric layer integrated with the high-k dielectric layer into a single constitution having the high-k dielectric layer being between the gate of the elastic transistor and the at least one other stretchable dielectric layer, wherein k, representing “dielectric constant”, is not less than four.

2. The apparatus of claim 1, wherein the elastic transistor is configured as a semiconductor transistor with the high-k layer including a synthetic rubber derived from different organic compounds, and said at least one other stretchable dielectric layer including a passivation material, and wherein the high-k layer and said at least one other stretchable dielectric layer are cooperatively arranged to provide a dielectric-semiconductor interface that facilitates reduced or minimum trap density for efficacious charge transportation and small transistor hysteresis.

3. The apparatus of claim 1, wherein the operation is a stable or steady-state operation with at least one of the following: the stretchable high-k multi-layer dielectric has a dielectric constant of not less than 10, and the operation manifests a carrier mobility of greater than 0.1 cm²/V-per-sec.

4. The apparatus of claim 1, wherein the stretchable high-k multi-layer dielectric being non-soluble in aqueous solution, during the operation.

5. The apparatus of claim 1, wherein the driving voltage is in a range of 10 V to a 0.5 V, and the operation is maintained while apparatus or the elastic transistor is under a strain of at least 25%.

6. The apparatus of claim 1, wherein stretchable high-k multi-layer dielectric is to provide the operation while being strained in a range that from 50% strain to 100% strain, and the driving voltage is in a range that does not exceed 3 V and that is not lower than 0.75 V.

7. The apparatus of claim 1, wherein the elastic transistor is configured as a synaptic transistor with the high-k dielectric layer having a border interface region characterized as one of a polycation interface and a polyanion interface, and said at least one other stretchable dielectric layer corresponding to an interfacial portion along an outer border of the high-k dielectric layer.

8. The apparatus of claim 1, wherein the operation manifests a carrier mobility of greater than 0.5 cm²/V-per-sec., and the operation occurs while the apparatus is submerged in an aqueous solution for at least one hour.

9. The apparatus of claim 1, wherein the transistor is a synaptic transistor, the high-k dielectric layer includes a single ion conductor, and said at least one other stretchable dielectric layer corresponds to an interfacial portion facing away from the gate, being along an outer border of the high-k dielectric layer with a thickness of not greater than several atomic layers, and having ionic conducting material to which one polarized-type of ion, as a anion or cation, is fixed.

10. The apparatus of claim 1, further including a neuromorphic circuit, including the transistor and closed-loop signal processing circuitry, to facilitate electrical stimulation of nerves with frequency encoding to generating different levels and/or patterns of signal output.

11. The apparatus of claim 1, wherein the elastic transistor, the high-k dielectric layer and said at least one other stretchable dielectric layer are monolithically integrated into a single constitution, the high-k dielectric layer includes a single ion conductor, and said at least one other stretchable dielectric layer has an interfacial portion being a blend of the high-k dielectric layer and an adjacent substrate and having a thickness not greater than 20 nm, and the apparatus further include a data encoding circuit which is cooperatively arranged with the elastic transistor, the high-k dielectric layer and said at least one other stretchable dielectric layer, to form a neuromorphic system to emulate simultaneously closed-loop sensory encoding and mechanical softness of natural skin.

12. The apparatus of claim 1, further including transistor circuitry, wherein the stretchable high-k multi-layer dielectric is integrated with synaptic transistor circuitry, and the synaptic transistor circuitry is to be driven, by a low voltage that corresponds to a voltage in a low-voltage range of less than 10 V to 0.5 V.

13. The apparatus of claim 1, wherein the elastic transistor is a semiconductor transistor for which the at least one other stretchable dielectric layer has a low dielectric constant and is to facilitate a minimized trap density for efficacious charge transportation and small transistor hysteresis, the apparatus further includes another elastic transistor, characterized by the elastic transistor of claim 1, in which the high-k dielectric layer has a border region with one of a polycation interface and a polyanion interface, and wherein the other elastic transistor is to provide stable operation while submerged in an aqueous solution and is to be stretchable under a strain of at least 25%.

14. The apparatus of claim 1, wherein the elastic transistor, the high-k dielectric layer and said at least one other stretchable dielectric layer are cooperatively configured into an integrated constitution with signal-processing circuitry for multimodal reception in response to stimuli, generated simultaneously or nearly simultaneously from a biological structure in multiple modalities, by using nerve-like pulse trains.

15. The apparatus of claim 1, wherein the transistor is a semiconductor transistor, the high-k dielectric layer includes a synthetic rubber derived from different organic compounds one of which is linked to nitrile, and said at least one other stretchable dielectric layer faces away from the gate and corresponds to an SEBS passivation layer.

16. The apparatus of claim 1, wherein the transistor is a semiconductor transistor, and said at least one other stretchable dielectric layer: faces away from the gate and facilitates a minimized trap density for efficacious charge transportation and small transistor hysteresis, corresponds to a passivation layer, has a dielectric constant that is below 4.

17. The apparatus of claim 1, wherein the transistor is a semiconductor transistor, and said at least one other stretchable dielectric layer: faces away from the gate, facilitates efficacious charge transportation and small transistor hysteresis, and has a dielectric constant that is not greater than 3.

18. The apparatus of claim 1, wherein the transistor is a semiconductor transistor, the high-k dielectric layer include a synthetic rubber derived from different organic compounds one of which is linked to nitrile, and said at least one other stretchable dielectric layer faces away from the gate and includes portions and includes: a hydrophobic octadecyltrimethoxysilane (OTS) modification layer, and an SEBS passivation layer or coating between the OTS modification layer and the high-k dielectric layer.

19. The apparatus of claim 1, further including a set of cooperatively-operative transistors, each of the transistors characterized as the elastic transistor and the stretchable high-k multi-layer dielectric, wherein the set of cooperatively-operative transistors includes transistor circuitry configured to sense at least one of pressure and temperature.

20. A method comprising:
operating an elastic transistor, in response to a driving voltage while the elastic transistor is being stretched under a strain of at least 25%; and
causing, while the elastic transistor is being operated in response to the driving voltage, electrons and/or holes to flow via a stretchable high-k multi-layer dielectric, wherein the stretchable high-k multi-layer dielectric has integrated layers including a stretchable high-k multi-layer dielectric and at least one other stretchable dielectric layer, with the high-k dielectric layer between a gate of the elastic transistor and the at least one other stretchable dielectric layer, and with each of the stretchable high-k multi-layer dielectric and the high-k dielectric layer having respective dielectric constants of not less than four.
